(19) United States
(12) Patent Application Publication
(10) Pub. No.: US 2026/0269568 A1
(43) Pub. Date: Sep. 10, 2026

(54) SURFACE EMITTING LASER, METHOD FOR FABRICATING SURFACE EMITTING LASER

(71) Applicant: SANOH INDUSTRIAL CO., LTD., Tokyo (JP)

(72) Inventor: Srinivas Gandrothula, Koga-shi, Ibaraki (JP)

(21) Appl. No.: 19/161,096

(22) PCT Filed: Mar. 7, 2023
(86) PCT No.: PCT/JP2023/008679

§ 371 Date: Aug. 29, 2025

(51) Int. Cl. H01S 5/183; H01S 5/028

(52) U.S. Cl. CPC H01S 5/18311; H01S 5/028; H01S 5/18361

(57) ABSTRACT

A vertical cavity surface emitting laser includes an oxide substrate having a first face and a second face at an opposite side from the first face; a semiconductor section disposed on the first face; a AR layer disposed between the semiconductor section and the first face; a first DBR mirror; and a second DBR mirror disposed at a curved surface of the second face. The first DBR mirror, the semiconductor section, the AR layer, the oxide substrate, and the second DBR mirror are arranged in a first axial direction to form an extended cavity. The semiconductor section is disposed between the AR layer and the first DBR mirror, and includes a p-type III nitride region, a III nitride region, and a III nitride active region between the p-type and n-type III nitride regions.

### TECHNICAL FIELD

This invention relates to an extended cavity III-nitride vertical cavity surface emitting laser (VCSEL) and a method of fabricating an extended cavity III-nitride VCSEL.

### BACKGROUND ART

Surface emitting lasers are known as vertical cavity surface emitting lasers (VCSELs). A VCSEL comprises a semiconductor active region disposed between an n-side semiconductor region and a p-side semiconductor region, and two distributed Bragg reflectors, which are referred to as DBRs, acting as high reflective mirrors. The semiconductor active region, also known as a gain medium, is disposed between the two DBRs such that the two DBRs and the semiconductor active region form an optical cavity. The n-side and p-side regions inject respective carriers, i.e., electron and hole, to the active region, and these carriers recombine in the active region to generate light. The light or electromagnetic radiation thus generated is reflected a number of times by the DBRs to travel in the optical cavity, leading to lasing. The VCSEL provides one of the DBRs with a less reflectance mirror, which is used to emit the laser beam.

Gallium nitride (GaN) VCSELs have recently been receiving increasing research attention due to their ability to emit in the visible and ultraviolet (UV) regions. This opens up a variety of new application space in displays, solid state lighting including automotive lighting and residential lighting, sending and communications. One particularly most exciting application is when blue emitting GaN VCSELs could couple with phosphor to act as a both natural light emitting source and data transmission device simultaneously. This application would address the all the new AR/VR applications, smartphone and normal displays in a new dimension by adding a communication feature to each light emitting pixel.

This application references a number of patent or non-patent publications as indicated throughout the specification by their reference numbers within brackets, i.e., [ ]. A list of the publications ordered according to these reference numbers can be found below in the section entitled “Non Patent Literature” or “Patent literature”.

### CITATION LIST

### Non Patent Literature

NPL 1: Appl. Phys. Express 12, 044004(2019 )

NPL 2: Sci. Rep. 8, 10350(2018)

NPL 3: Applied Phys. Lett. 83, 2121(2003)

NPL 4: Appl. Phys. Express 2008, 1, 121102.

NPL 5: Appl. Phys. Express 2012, 5, 092104

NPL 6: Optics Express, 27, 24717(2019)

NPL 7: Appl. Phys. Express, 13, 041003(2020)

NPL 8: Appl. Phys. Express, 14,031002(2021)

NPL 9: Applied Phys. Lett. 119, 142103(2021)

NPL 10: Crystals, 11 (12) 1563, (2021)

NPL 11: M. B. Stern and T. R. Jay, “Dry etching for coherent refractive microlens arrays,” Opt. Eng. 33, 3547-3551 (1994)

### SUMMARY OF INVENTION

### Technical Problem

VCSEL optical cavity defined by two planar DBR mirrors suffers an excessive diffraction loss with increasing cavity length. Using the curved mirror provides the VCSEL with a long optical cavity and the curved lens refocuses electromagnetic filed into the gain medium there by reducing diffraction loses that originate from the longer cavity length [NPL 1-NPL2]. Up until 2022, long cavity designs from Sony held the performance records for CW output power of 15.8 mW, threshold current 0.25 mA, and wall plug efficiency (WPE) 9.5%. High efficiency VCSEL operation can be achieved by tailoring the cavity mode to align with the gain spectrum. The curved mirror is necessary because it prevents diffraction and scattering loss that would otherwise occur in long GaN cavities. As cavity length increases, so does diffraction loss, the typical gain of GaN quantum wells is approximately 1%, so the exceeding diffraction and scattering loss due to long cavities and imperfections at the interfaces can quickly deteriorate device performance for GaN cavities longer than 10 micrometers. In case of very short cavity length, for example, one or two optical wavelengths thick, mode alignment with gain spectrum is extremely difficult due to large mode separation, thus decreases yield and lasing efficiency of the devices. As the cavity length increases mode spacing decreases resulting an increase in overlapping probability between cavity mode and the gain spectrum thus enabling a higher yield of lasing devices.

However, in long cavity achieving transparency for all of the VCSEL device layers except the active region to the propagating electromagnetic radiation is a challenging task. In all the reported literature, the curved DBR mirror is formed either on the back side of the native III-nitride substrate or on the p-side of the device, even though this structure of VCSEL doesn't pose a very strict requirement for the substrate removal but moderate losses will be introduced by remaining host substrate. The curved mirror approach proposed in Refs. [NPL 1] and [NPL 2] still use a significant portion of the native host substrate even after employing polishing and etching lens structure on the semiconductor host substrate to formulate the curved n-side DBR mirror. Though this is a good approach, but the method is designed for homoepitaxy of device layers containing Ga, N, In, Al alloys. Additionally, doping level of the host substrate used in the long cavity should be maintained low to pin absorption losses. Therefore, the host substrate is first thinned in thickness to reduce absorption loss in the cavity. Thinning the substrate can be a difficult process to control and may damage the wafer because the substrate has to be thinned from an initial thickness of 300 to 400 micrometers to a target thickness of 10 to 30 micrometers to provide the VCSEL with the cavity. Otherwise, an unintentional absorption loss is added in every round trip of the electromagnetic radiation resulting a reduced lasing probability. Alternatively, researchers in [NPL 3] demonstrated GaN VCSEL operation in an extended cavity scheme by directly growing device structure on absorption less sapphire substrate. But such a method still poses a limit on crystalline quality due to considerable lattice mismatch between device layers and the sapphire substrate. Therefore, lifetime and yield of such devices would be a problem.

It would be preferred to keep the absorption source as thin as possible while keeping a stable laser operation. Ideally, the bottom-mirror has to be positioned to form the cavity with the top and bottom mirrors being located close to each other to allow the formation of the optical cavity, which results ultimately removal of the native substrate. When VCSEL device layers grown on hetero-substrate such as Sapphire or Si, III-nitride VCESL devices can be easily removed via laser lift-off (LLO) [NPL 4] or chemical etching. However, GaN heteroepitaxy on sapphire has its limit in crystal quality. Conventional LLO process is not acceptable to GaN homoepitaxy. Alternatively, removal of III-nitride device layers from GaN homoepitaxy has been reported [NPL 5] and is still a very interesting topic [NPL 6-NPL 10].

Longer the cavity better the stability in terms of lasing as well as thermal drift. Alternatively, extended cavity VCSEL designs can be realized by reattaching a lossless transparent oxide (TO) materials such as such as Al2O3, ZnO and Ga2O3 etc after carefully removing VCSEL device layers from the native growth substrate or hetero substrate. However, surface preparation below sub nanometer must be achieved both on the attaching TO substrate and on the removed device layers. However, at the GaN/Oxide interface when reattached, the refractive index difference leads to potentially unwanted reflections. In the case that these reflections lead to detrimental device performance, an antireflection coating can be added at the interface to suppress unwanted reflections. All of these procedures time consuming, leads to yielding issues on top of an additional added cost.

Considering all these disadvantages, it is an object to provide a structure of a III nitride-based VCSEL and a method for fabricating a III nitride-based VCSEL with an extended cavity feature. It is another object to provide a single step integration solution for realizing an extended cavity without involving complex bonding procedure with an external TO substrate and/or substrate removal.

### Solution to Problem

One configuration of the present disclosure is a VCSEL, which comprises: an oxide substrate having a first face and a second face at an opposite side from the first face, the second face including a curved surface; a semiconductor section disposed on the first face of the oxide substrate; a lossless antireflective (AR) layer disposed between the semiconductor section and the first face of the oxide substrate; a first distributed Bragg reflector (DBR) mirror, the semiconductor section being disposed between the AR layer and the first DBR mirror; and a second DBR mirror disposed at the curved surface of the oxide substrate, the first DBR mirror, the semiconductor section, the AR layer, the oxide substrate, and the second DBR mirror being arranged in a first axial direction to form an extended cavity, the semiconductor section including a p-type III nitride region, a III nitride region, and a III nitride active region between the p-type III nitride region and the III nitride region, the p-type III nitride region, the III nitride active region, and the III nitride region being arranged in the first axial direction, and the III nitride region including an n-type III nitride region.

Another configuration of the present disclosure is a method for fabricating a VCSEL, and the method comprising: preparing a starting base, the starting base including an oxide base, a III nitride template plug, and a lossless antireflective (AR) layer, the oxide base having a first face and a second face at an opposite side from the first face of the oxide base, and the AR layer and the III nitride template plug being located at the first face of the oxide base; growing a III nitride region from the III nitride template plug on the AR layer; after growing the III nitride region, growing a semiconductor laminate including an n-type III nitride region, a III nitride active region, and a p-type III nitride region; processing the oxide base at the second face thereof to form an oxide substrate having a curved surface, the curved surface being disposed at an opposite side from a first face of the oxide substrate; after growing the semiconductor laminate, forming a first distributed Bragg reflector (DBR) laminate on the first face of the oxide substrate; and forming a second DBR laminate on the curved surface of the oxide substrate.

### Advantageous Effects of Invention

The above configurations can provide a structure of a III VCSEL with an extended cavity feature and a method for fabricating a VCSEL with an extended cavity feature.

### BRIEF DESCRIPTION OF DRAWINGS

FIG. 1 is a schematic cross-sectional view showing VCSELs with a thick TO block according to an embodiment of the present disclosure.

FIG. 2A is a cross-sectional view showing an extended cavity VCSEL according to the present embodiment of the present disclosure, taken along I-I line shown in FIG. 2B.

FIG. 2B is a schematic top view showing the VCSEL according to the present embodiment of the present disclosure.

FIG. 3 is a cross-sectional view showing an extended cavity VCSEL according to the present embodiment of the present disclosure, taken along I-I line shown in FIG. 2B.

FIG. 4A is a schematic view showing template containing TO substrate.

FIG. 4B is a schematic view showing etched template plug on the TO substrate.

FIG. 4C is a schematic view showing AR layer covering the TO substrate except template plug.

FIG. 4D is a top view showing stripe like pattern for the template plug.

FIG. 5A is a schematic cross-sectional view showing an extended cavity VCSEL with tunnel junction as current spreading layer according to a second embodiment of the present disclosure, taken along II-II line shown in FIG. 5B.

FIG. 5B is a schematic top view showing the VCSEL according to the second embodiment of the present disclosure.

FIG. 6A is a schematic cross-sectional view showing an extended cavity VCSEL with buried tunnel junction as current spreading layer according to a third embodiment of the present disclosure, taken along III-III line shown in FIG. 5B.

FIG. 6B is a schematic top view showing the VCSEL according to the third embodiment of the present disclosure.

FIG. 7A is a schematic cross-sectional view showing base layers grown using ELO process on stripe like.

FIG. 7B is a schematic cross-sectional view showing base layers grown using ELO process on stripe like.

FIG. 8 is a schematic cross-sectional view showing Semiconductor device layers on the polished pallets.

FIG. 9 is a schematic view showing a major step 1 in the VCSEL fabrication method according to the present embodiment.

FIG. 10 is a schematic view showing a major step 2 in the VCSEL fabrication method according to the present embodiment.

FIG. 11 is a schematic view showing a major step 3 in the VCSEL fabrication method according to the present embodiment.

FIG. 12 is a schematic view showing a major step 4 in the VCSEL fabrication method according to the present embodiment.

FIG. 13 is a schematic view showing a major step 5 in the VCSEL fabrication method according to the present embodiment.

FIG. 14 is a schematic view showing a major step 6 in the VCSEL fabrication method according to the present embodiment.

FIG. 15 is a schematic view showing a major step 7 in the VCSEL fabrication method according to the present embodiment.

FIG. 16 is a schematic view showing a major step 8 in the VCSEL fabrication method according to the present embodiment.

FIG. 17 is a schematic view showing a major step 9 in the VCSEL fabrication method according to the present embodiment.

FIG. 18 is a schematic view showing a major step 10 in the VCSEL fabrication method according to the present embodiment.

FIG. 19 is a schematic view showing a major step 11 in the VCSEL fabrication method according to the present embodiment.

FIG. 20 is a schematic view showing a major step 12 in the VCSEL fabrication method according to the present embodiment.

FIG. 21A is a schematic cross-sectional view showing a major step 13 in the VCSEL fabrication method according to the present embodiment, taken along x-y line shown in FIG. 21B.

FIG. 21B is a schematic top view showing the VCSEL according to the present embodiment of the present disclosure.

FIG. 22A is a schematic cross-sectional view showing a major step 14 in the VCSEL fabrication method according to the present embodiment, taken along x-y line shown in FIG. 22B.

FIG. 22B is a schematic top view showing the VCSEL according to the present embodiment of the present disclosure.

FIG. 23A is a schematic cross-sectional view showing a major step 15 in the VCSEL fabrication method according to the present embodiment, taken along x-y line shown in FIG. 23B.

FIG. 23B is a schematic top view showing the VCSEL according to the present embodiment of the present disclosure.

FIG. 24 is a schematic view showing a major step 16 in the VCSEL fabrication method according to the present embodiment.

FIG. 25 is a schematic view showing a major step 17 in the VCSEL fabrication method according to the present embodiment.

FIG. 26 is a schematic view showing a major step 18 in the VCSEL fabrication method according to the present embodiment.

FIG. 27 is a top view showing triangular lattice pattern for the template plug.

FIG. 28 is a top view showing triangular lattice pattern for the template plug with guide marks.

FIG. 29 is a top view showing the ELO device pallets on the AR mask without guiding marks.

FIG. 30A is a top view showing the ELO device pallets on the AR mask with guiding marks.

FIG. 30B is an enlarged view of the guideline marker of FIG. 30A.

FIG. 30C is a sketch of growth mechanism for hexagonal pyramids.

FIG. 30D is a sketch of growth mechanism for obtaining pallets.

FIG. 31A is an illustration of HCP VCSELs on a single template plug originated layers.

FIG. 31B is an illustration of HCP VCSELs on a single template plug originated layers and laser beam impressions.

FIG. 32A is an illustration to fabricate lenses in a circular shape to address single triangular lattice III-nitride plug.

FIG. 32B is an illustration to fabricate lenses in a circular shape to address single triangular lattice III-nitride plug.

FIG. 32C is an illustration to fabricate lenses in a circular shape to address single triangular lattice III-nitride plug.

FIG. 32D is an illustration to fabricate lenses in a circular shape to address single triangular lattice III-nitride plug.

FIG. 33 is an illustration of HCP VCSELs on a single template plug originated layers.

FIG. 34 is an illustration of HCP VCSELs on a single template plug originated layers and laser beam impressions.

FIG. 35A is an illustration to fabricate lenses in a circular shape to address single triangular lattice III-nitride plug.

FIG. 35B is an illustration to fabricate lenses in a circular shape to address single triangular lattice III-nitride plug.

FIG. 35C is an illustration to fabricate lenses in a circular shape to address single triangular lattice III-nitride plug.

FIG. 35D is an illustration to fabricate lenses in a circular shape to address single triangular lattice III-nitride plug.

FIG. 36 is a sketch of separating mechanisms for the fabricated VCSELs, laser stealthing is used.

FIG. 37 is a sketch of separating mechanisms for the fabricated VCSELs, a cleaving is used.

FIG. 38A is an enlarged view of the guideline marker of FIG. 37.

FIG. 38B is a sketch of separating mechanisms for the fabricated VCSELs, a cleaving is used.

FIG. 38C is a sketch of separating mechanisms for the fabricated VCSELs, a cleaving is used.

FIG. 38D is a sketch of separating mechanisms for the fabricated VCSELs, a cleaving is used.

FIG. 39 is a top view of a VCSEL in a step grown from III-nitride template plugs by epitaxial lateral overgrowth to form III-nitride islands.

FIG. 40A is a schematic cross-sectional view showing a major step 14 in the VCSEL fabrication method according to the fourth embodiment, taken along IV-IV line shown in FIG. 40B.

FIG. 40B is a schematic top view showing the VCSEL at step 14 according to the fourth embodiment of the present disclosure.

FIG. 41 is a schematic top view showing the VCSEL at step 15 according to the fourth embodiment of the present disclosure.

FIG. 42A is a schematic top view showing the HCP VCSELs as a block.

FIG. 42B is a schematic view showing the HCP VCSELs as a block.

FIG. 43 is a schematic view showing photon recycling phenomenon illustration.

### DESCRIPTION OF EMBODIMENTS

Teachings of the present invention can be readily understood by considering the following detailed description with reference to the accompanying drawings shown as examples. Referring to the accompanying drawings, a schematic view showing a vertical cavity surface emitting laser (VCSEL), and a method for fabricating a VCSEL according to the present disclosure will be described below. To facilitate understanding, identical reference numerals are used, where possible, to designate identical elements that are common to the figures.

An embodiment of the present invention concerns the placement of a curved mirror on a TO material. AR layer is embedded between plano-curved mirror resonant cavity of the VCSEL. Using curved mirror allows for the use of longer cavity devices with lower diffraction loss via refocusing (nearly 90%) of the electromagnetic radiation into the gain medium. Negligibly small absorption operation with a curved mirror is made possible by employing lossless transparent oxide (TO) material comprises ZnO, Ga₂O₃, or Al₂O₃ as majority of the cavity. The present invention allowing the realization of much longer cavity, better thermal performing VCSEL devices.

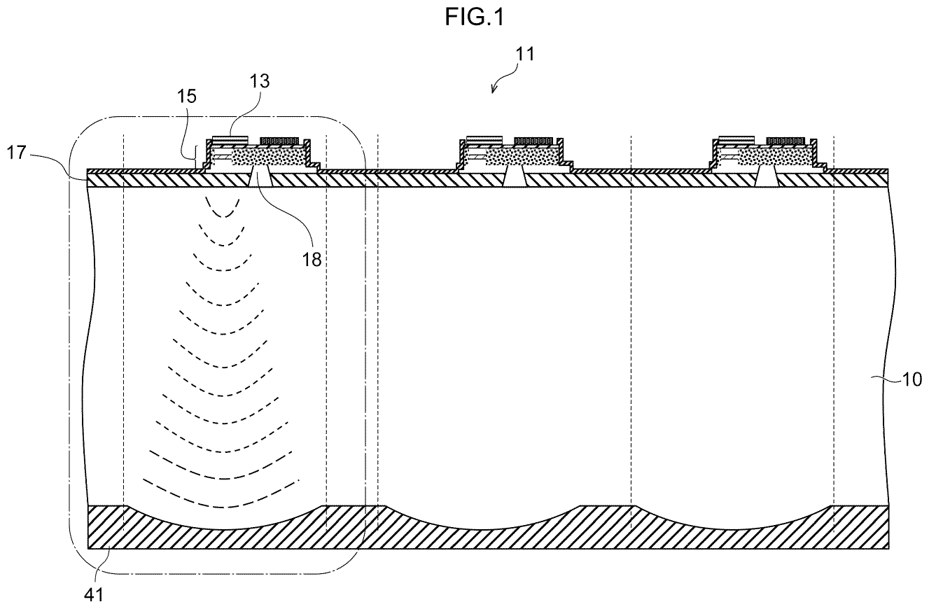

FIG. 1 is a simple schematic view showing an extended cavity VCSEL according to the present embodiment. A VCSEL 11 comprises a curved distributed Bragg reflector (DBR) 41 on a TO material (bottom mirror) which is integrated in the design in a single step and a semiconductor section 15 with a plane DBR (top-mirror) 13. Curved DBR 41 formed on an extended cavity oxide substrate 10 which was monolithically integrated via AR layer 17. The AR layer 17 functions as perfect transmitter for the electromagnetic radiation, and an attachment element for the oxide substrate 10 and also supports for the formation of III-nitride alloy layers; semiconductor section 15. Semiconductor section VCSEL formed via ELO layers includes a p-type III nitride region 23, a III nitride region 25 including an n-type III nitride region, and a III nitride active region 27 between the p-type III-nitride region 23 and the n-type III nitride region of the III nitride region 25.

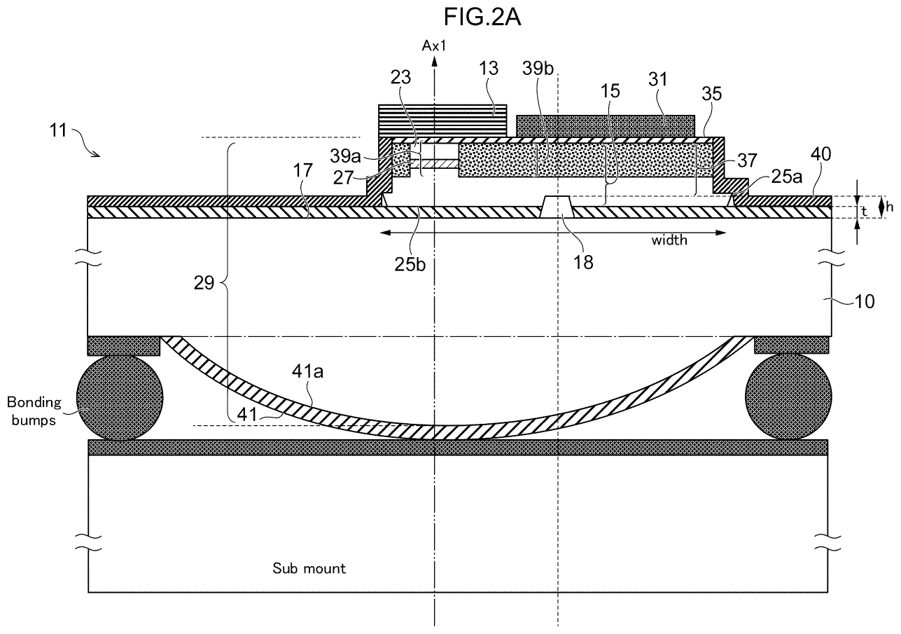

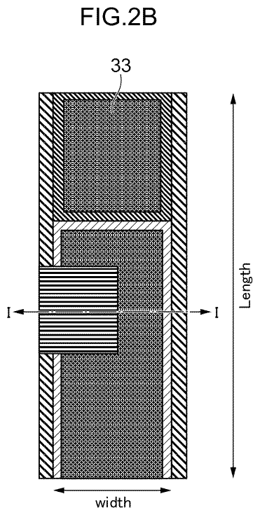

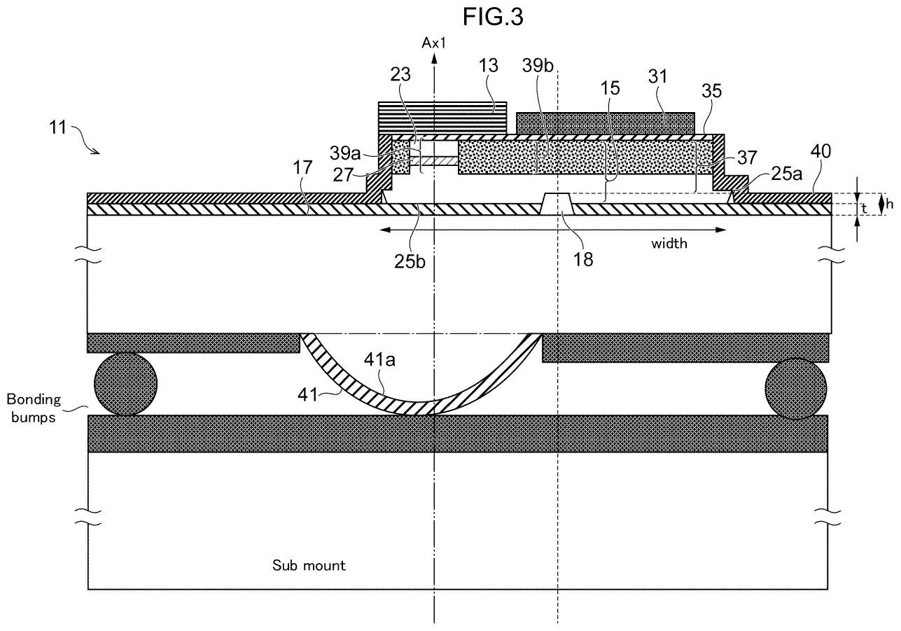

FIG. 2A show a magnified view of the device layers cross-section with a bonded sub-mount and a top-view of the device in FIG. 2B to identify electrodes configuration. FIG. 3 is also a representation other possible device configuration.

The semiconductor section 15 is laterally grown from an exposed (h-t) sidewall region and the top surface of the III-nitride template plug 18.

The template plug 18 connects TO substrate 10 and the semiconductor section 15. Therefore, the template plug 18 serves as a thermal path for the VCSEL device when operated. Utilizing better thermal conductivity TO substrate material and allowing thermal energy to sink into the TO material via template plug 18, the proposed VCSEL device can have better thermal characteristics. A crystal orientation of the III-nitride template plugs 18 is c-plane, semipolar or non-polar.

AR layer 17 preferably made of all dielectrics can be employed as a supporting structure for the laterally growing semiconductor section 15 from the III-nitride template plug 18. By laminating a AR layer 17 before semiconductor section 15 growth offers a single step integration of TO substrate 10 to very thin semiconductor section 15 without substrate removal and bonding. AR layer 17 is a one single structure offers transparent window for resonating optical wavelength. AR layer 17 surface roughness is below 1 nm. Preferably, AR layer 17 is a single layer allowing electromagnetic radiation of interest into the cavity and to the TO substrate, alternatively, 17 can be a multiple layer structure.

AR layer 17 has a through hole extending in a first axial direction Ax1, the III nitride template plug 18 is disposed in the through hole and extending from the first face of the oxide substrate 10 to the semiconductor section 15 in the through hole. The curved surface of the oxide substrate 10 has a center line, and the III nitride template plug 18 and the center line of the curved surface are misaligned with each other.

A VCSEL 11 comprises a DBR 13 and a semiconductor section 15 formed over AR layer 17. The DBR 13 includes first dielectric layers and second dielectric layers alternatively arranged in a first axial direction AX1, and the material of the first layers is different from the second layers. The semiconductor section 15 includes a p-type III nitride region 23, a III nitride region 25 including an n-type III nitride region, and a III nitride active region 27 between the p-type III-nitride region 23 and the n-type III nitride region of the III nitride region 25. The p-type III nitride region 23, the III-nitride active region 27, and the n-type III nitride region of the III nitride region 25 are arranged in the first axial direction Ax1. The semiconductor section 15, and the DBR 13 are arranged in the first axial direction Ax1 to form an optical cavity 29. The III nitride active region 27 is grown to form a quantum well structure configured to generate light having a wavelength in a first reflection spectrum of the first DBR 13, and a second reflection spectrum of the second DBR 41.

The VCSEL 11 further includes an anode electrode 31 and a conductive layer 35. The conductive layer 35 connects the anode electrode 31 with the p-type III nitride region 23. The conductive layer 35 may include either a III nitride semiconductor, such as p-type GaN, or a conductive inorganic material, such as indium tin oxide (ITO), or both. The variations of conducting layer described in later sections. In an example, the DBR 13 can be in contact with the conductive layer. If needed, the semiconductor section 15 may further include a tunnel junction disposed between the p-type III nitride region 23 and the conductive layer 35, which has the n-type conductivity. The VCSEL 11 is constructed without using III-nitride material on the oxide substrate 10 side of the AR layer 17.

In the VCSEL 11 that provides the semiconductor section 15 with a mesa 37, the mesa 37 includes the p-type III nitride region 23, the III nitride active region 27 and a part of the n-type III nitride region of the III nitride region 25. The mesa 37 is located on the reminder of the n-type III nitride region of the III nitride region 25, and at the bottom of the mesa 37, the mesa 37 is surrounded by the n-type III nitride front face 25a prolonged along the length of the chip of the III nitride region 25. The cathode electrode 33 may be disposed on the n-type III nitride front face 25a of the III nitride region 25 along the length by opening a patch. A material omni-directional reflector 40 to reflect the resonating wavelength towards cavity is placed as a passivation layer between the cathode electrode 33 and anode electrode 31. The VCSEL 11 includes a cathode electrode 33. The cathode electrode 33 is electrically connected with the n-type III nitride region of the III nitride region. As shown in FIG. 2B, the cathode electrode 33 in contact with front of the n-type III nitride region of the III nitride region along the length of the ELO layer.

The cavity 29 has a total cavity length L_{CAV}, which can be defined as a distance between the curved TO substrate material 41a and the planar surface of conductive layer 35 before placing DBR 13. Present VCSEL 11 can use 50 to 1000 micrometers of TO substrate 10 as an extended cavity 29 provided semiconductor section 15 is roughly to 0.5 to 4 micrometers. A length of the extended cavity 29 is more than 50 micrometers.

The semiconductor section 15 has a conductive aperture portion 39a and a less conductive portion 39b which surrounds the aperture conductive portion 39a. The aperture conductive portion 39a provides the VCSEL 11 with an electrical path from the anode electrode 31 to the cathode electrode 33. Carriers, such as electron and hole, flow through the electrical path, and are recombined in the III nitride active region 27 to generate light, which emits from one of the DBR 13.

The conductive aperture portion 39a is asymmetrically placed away from the template plug 18 to minimize overlap of the bouncing electromagnetic radiation between cavity mirrors with the template plug 18. Also, increasing the cavity length simply by utilizing thicker TO substrate 10 beam propagation path can be adjusted such that beam profile avoids any interaction with template plug 18. The asymmetric design can also assist in accommodating anode electrode 31 and cathode electrode 33 both on semiconductor surface. Furthermore, such an asymmetric design avoids defect region or an irregular region near the template plug 18 which may resulted due to etching or short range crystal defects that may occur near the template plug. Preferably ~3 micrometers from the template plug 18 sidewall should be avoided when placing conductive aperture region 39a. VCSEL blocks outer surface is coated with antireflective material to trap escaping photon.

An variant case was also described in the FIG. 3, where curved mirror axis is completely avoids any overlap with the template plug 18. Hexagonal closed packed (HCP) designs can be designed when default growth pattern of III-nitride layers was used for the maximum benefit. The HCP VCSELs are a new design concept for increasing packaging density. In this case, a plurality of semiconductor sections 15 are formed employing HCP closed packed hexagonal design growths, and the curved surfaces are a plurality of curved surfaces arranged corresponding to the plurality of semiconductor sections 15.

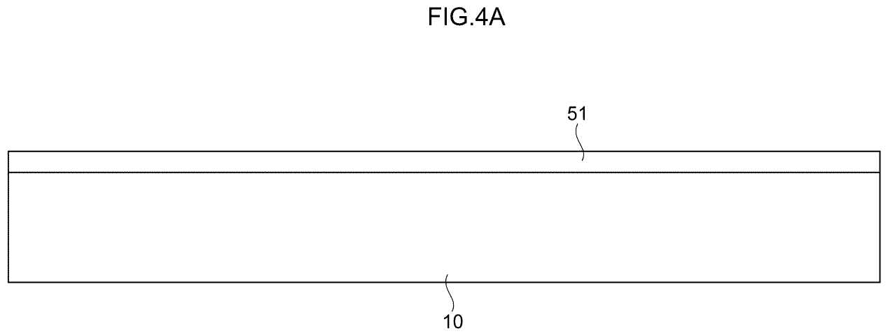

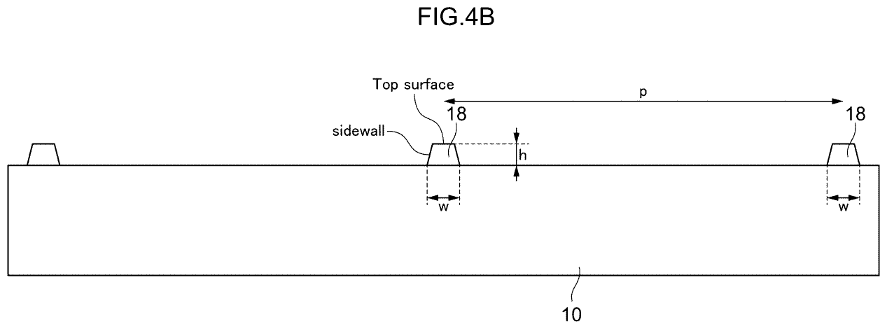

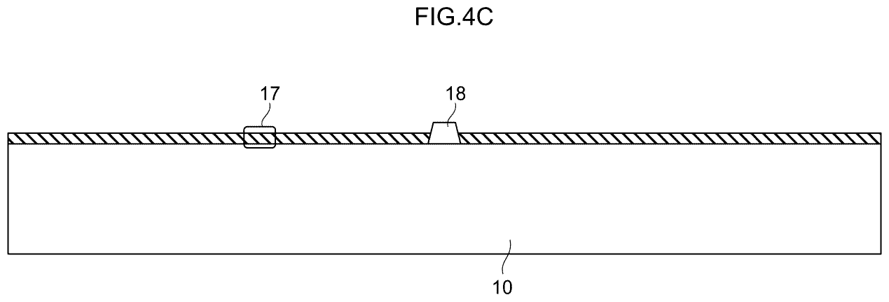

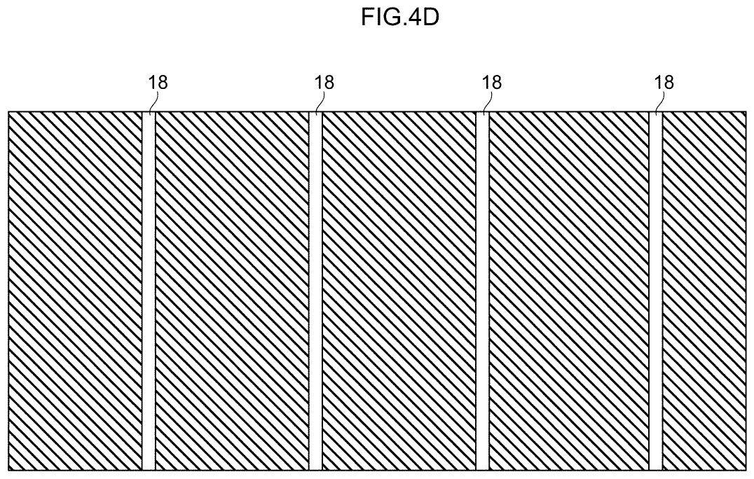

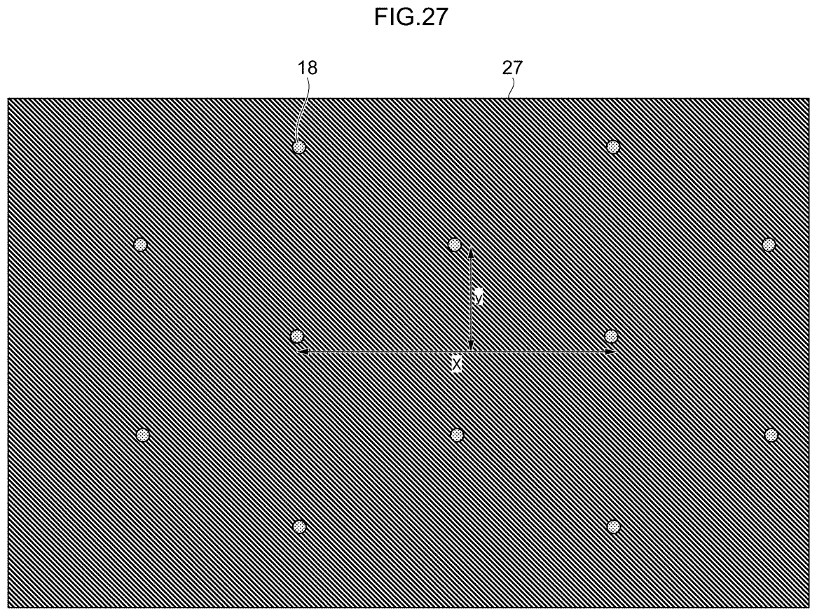

Referring to FIGS. 4A, 4B, 4C and 4D, an outlined description will be given of an exemplary fabrication process according to the present embodiment. First, an oxide substrate 10 containing a III-nitride template 51 is prepared as a starting base. Then a selective etching is performed to result a template plug 18 having a width w and height h on the oxide material substrate 10. Template plugs 18 can be placed near to each other or separated on the oxide substrate 10 depending on designs which will be discussed later. Some designs are shown in FIG. 4D and FIG. 27.

A step of preparing a starting base comprises: depositing a III nitride layer on the first face of the oxide base 10; patterning the III nitride layer to form the III nitride template plug 18; depositing multiple dielectric layers to cover the first face of the oxide base 10 and the III nitride template plug 18; and processing the multiple layers to form the AR layer 17 such that the III nitride template plug 18 is located in a through hole of the AR layer 17, and the III nitride template plug 18 has a height that is greater than a thickness of the AR layer 17.

FIG. 4C illustrates an AR layer 17 to partially embed the template plug 18. As described template plug 18 can be a single stripe shape as in FIG. 4D or circular patches of diameter <5 microns arranged in a 2D triangular lattice passion as in FIG. 27.

An example process includes the following step to realize VCSEL 11 with ITO as current spreading layer described in FIGS. 3A and 3B:
1. Preparing a template plug 18 on the TO material substrate.
2. Placing AR layer 17 all over the TO material substrate while partially exposing sidewalls and completely the top surface of the template plug 18.
3. Growing the unintentionally doped n−GaN layer from the exposed region of the template plug 18, wherein the growth is stopped after achieving total width of the layer around 30 to 200 microns including template plug 18.
4. Planarization performed.
5. Growing the following device layers in order on the planarized n−GaN layer: n−GaN for cladding and n-contacting, InGaN multi quantum wells, AlGaN electron blocking layer, p−GaN and p++ GaN.
6. Then, polishing back surface of the TO substrate material and transferring micro lens pattern through resist reflow and reactive ion etching.
7. Then using lensing function from the backside aperture is defined on the device layer surface.
8. Then conducting ion implantation to define aperture.
9. After surface cleaning, deposit a TCO, a transparent conducting oxide like ITO.
10. Define a mesa 37 to separate electrodes.
11. Passivate the contact regions with ODR material.
12. Depositing dielectric distributed Bragg reflector 13 on flat portion of the device layers.
13. Opening regions for anode and cathode electrode deposition.
14. Depositing electrode metal pads.
15. Depositing dielectric distributed Bragg reflector mirror 41 on the curved portion of TO substrate material.
16. Placing a bonding material on backside of the device.
17. Singularization of VCSEL chips.
18. Bonding to a sub-mount.
19. Used in user defined applications as a light source or sensor or both.

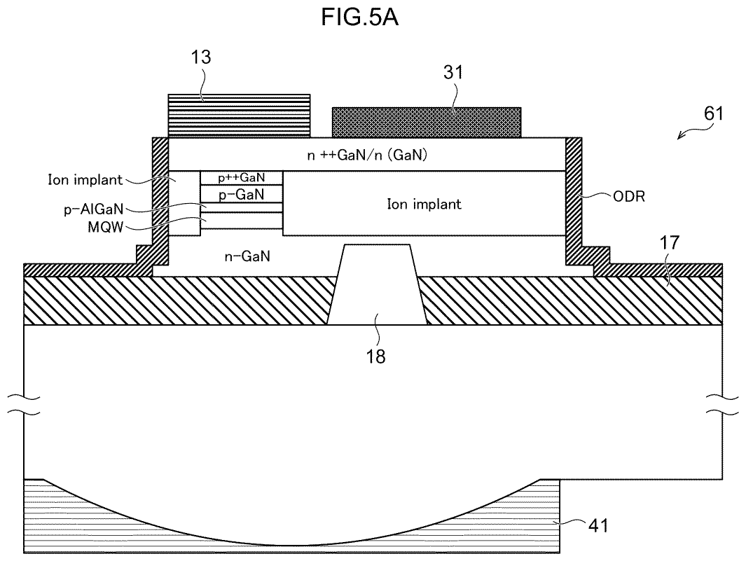

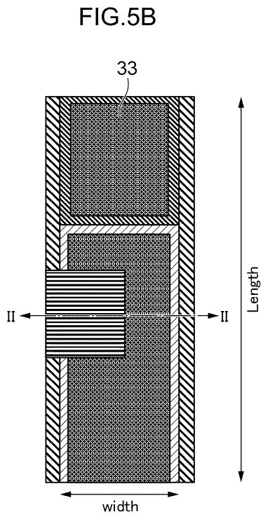

FIG. 5A is a schematic view showing a VCSEL according to a second embodiment of the present disclosure. FIG. 5B is schematic top view showing the VCSEL.

An example process includes the following step to realize VCSEL 61, with tunnel junction as a current spreading layer described in FIG. 5A.
1. Preparing a template plug 18 on the TO material substrate.
2. Placing AR layer 17 all over the TO material substrate while partially exposing sidewalls and completely the top surface of the template plug 18.
3. Growing the unintentionally doped n−GaN layer from the exposed region of the template step, wherein the growth is stopped after achieving total width of the layer around 30 to 200 microns including template plug 18.
4. Planarization performed.
5. Growing the following device layers in order on the planarized n−GaN layer: n−GaN for cladding and n-contacting, InGaN multi quantum wells, AlGaN electron blocking layer, p−GaN and p++ GaN.
6. Then, polishing back surface of the TO substrate material and transferring micro lens pattern through resist reflow and reactive ion etching.
7. Then using lensing function from the backside aperture is defined on the device layer surface.
8. Then conducting ion implantation to define aperture.
9. After surface cleaning, regrowing n++ GaN to complete tunnel junction.
10. Depositing n−GaN for contacting and current spreading.
11. Define a mesa 37 to separate electrodes.
12. Passivate the contact regions with ODR material.
13. Depositing dielectric distributed Bragg reflector 13 on flat portion of the device layers.
14. Opening regions for anode and cathode electrode deposition.
15. Depositing electrode metal pads.
16. Depositing dielectric distributed Bragg reflector mirror 41 on the curved portion of TO substrate material.
17. Placing a bonding material on backside of the device.
18. Singularization of VCSEL chips.
19. Bonding to a sub-mount.
20. Used in user defined applications as a light source or sensor or both.

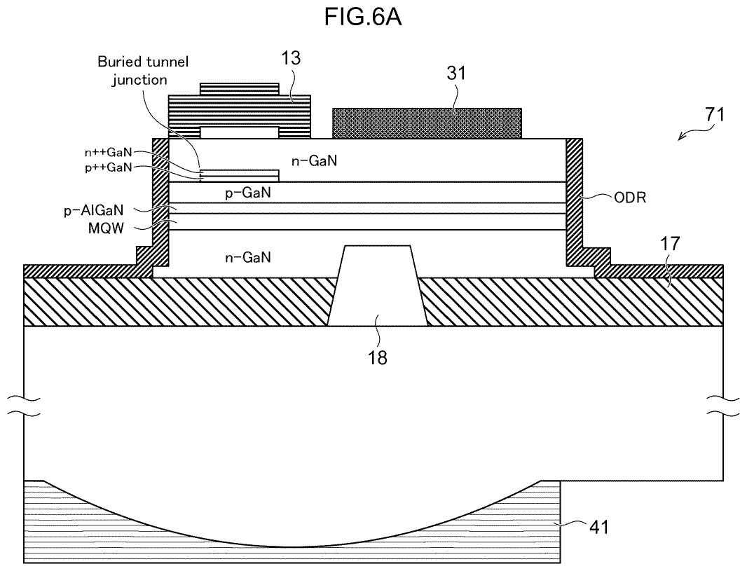

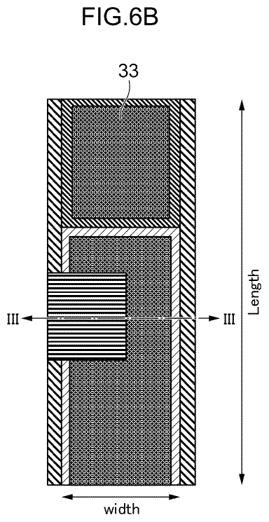

FIG. 6A is a schematic view showing a VCSEL according to a third embodiment of the present disclosure. FIG. 6B is schematic top view showing the VCSEL.

An example process includes the following step to realize VCSEL 71, with buried tunnel junction as aperture described in FIG. 6A.
1. Preparing a template plug 18 on the TO material substrate.
2. Placing AR layer 17 all over the TO material substrate while partially exposing sidewalls and completely the top surface of the template plug 18.
3. Growing the unintentionally doped n−GaN layer from the exposed region of the template plug 18, wherein the growth is stopped after achieving total width of the layer around 30 to 50 microns including template plug 18.
4. Planarization performed.
5. Growing the following device layers in order on the planarized n−GaN layer: n−GaN for cladding and n-contacting, InGaN multi quantum wells, AlGaN electron blocking layer, p−GaN and p++ GaN and n++ GaN.
6. Then, polishing back surface of the TO substrate material and transferring micro lens pattern through resist reflow and reactive ion etching.
7. Then using lensing function from the backside aperture is defined on the device layer surface.
8. Then define aperture mask, etch n++, p++ GaN expose underlying p−GaN.
9. After surface cleaning, regrowing n−GaN for contacting and current spreading, forms a buried tunnel junction.
10. Define a mesa 37 to separate electrodes.
11. Passivate the contact regions with ODR material.
12. Depositing dielectric distributed Bragg reflector 13 on flat portion of the device layers.
13. Opening regions for anode and cathode electrode deposition.
14. Depositing electrode metal pads.
15. Depositing dielectric distributed Bragg reflector mirror 41 on the curved portion of TO substrate material.
16. Placing a bonding material on backside of the device.
17. Singularization of VCSEL chips.
18. Bonding to a sub-mount.
19. Used in user defined applications as a light source or sensor or both.

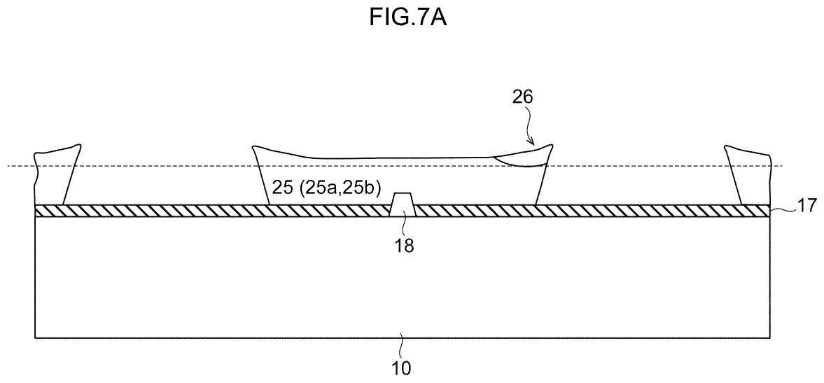

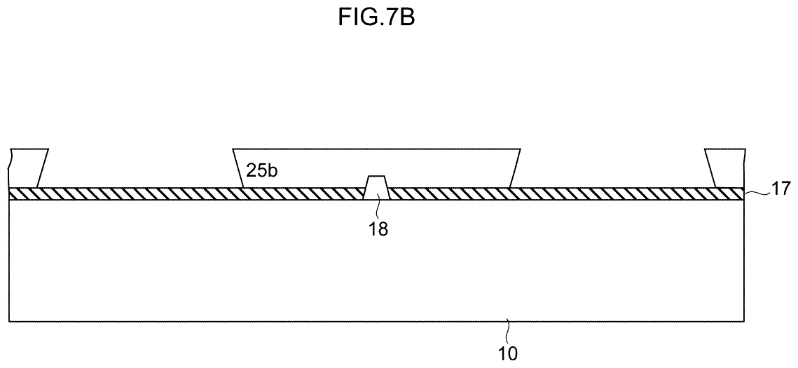

FIG. 7A is a sketch of III-nitride epitaxial layers, preferably n type doped GaN layer 25 epitaxially deposited. The III nitride region is grown from the III nitride template plug 18 by epitaxial lateral overgrowth to form a III nitride island. The III nitride island extends along a top face of the AR layer 17 from the III nitride template plug 18 outward, and the top face of the AR layer 17 has a roughness lower than one nanometer.

In the following description, III nitride can be deposited by, for example, metal organic chemical vapor deposition (MOCVD). The III-nitride n−GaN layer 25 extends outward from the template plug 18. Depending on the filling factor of the growth surface, III-nitride atoms may accumulate more at the edge of the III-nitride layer compared to the central portion of the layer 25. Which can be seen as edge growth 26 may serve as a disadvantage when continued for the growth of VCSEL device layers. In FIG. 7B, the III nitride layer thus deposited is polished to obtain a planer surface and adjust a cavity length of the VCSEL. HCP case is a picture of base layers after polishing.

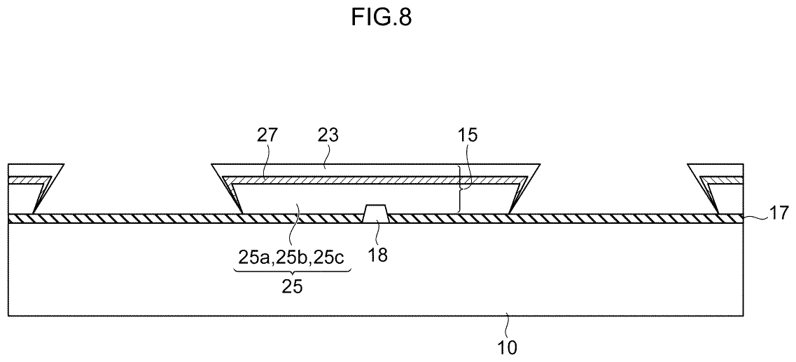

After the planarization of the III nitride layer 25b, as shown in FIG. 8, a semiconductor section 15 is grown which includes the III nitride region 25c, the III nitride active region 27, and the p-type III nitride region 23. The nitride region 25 can include GaN- or AlN-based material doped with n-type dopant, which allows the supply of electrons to the III nitride active region 27, and the p-type III nitride region 23 can include GaN- or AlN-based material doped with p-type dopant, which allows the supply of holes to the III nitride active region 27. The III nitride active region 27 can include GaN- or AlN-based material, such as GaN, InGaN, AlN or AlGaN. The III nitride active region 27 may be provided with a single layer or a quantum well structure, such as single quantum well (SQW) or multiple quantum wells (MQWs). If needed, the buried tunnel junction or tunnel junction layers must be grown after depositing the p-type III nitride region 23.

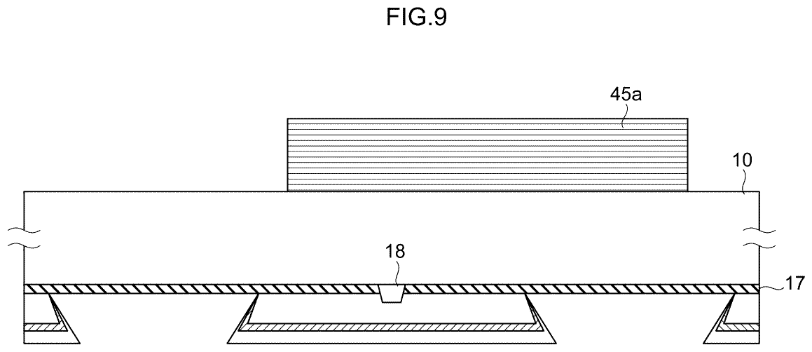

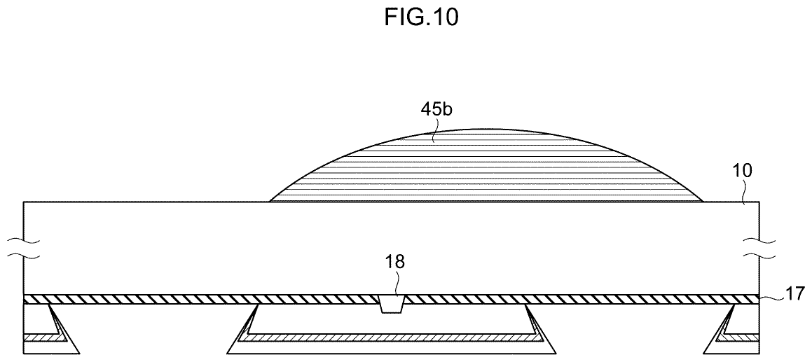

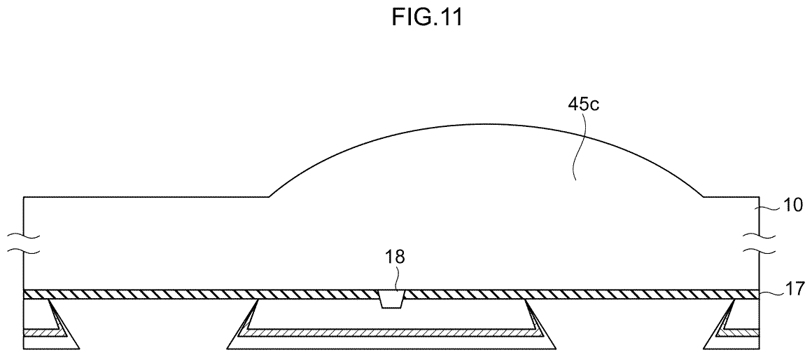

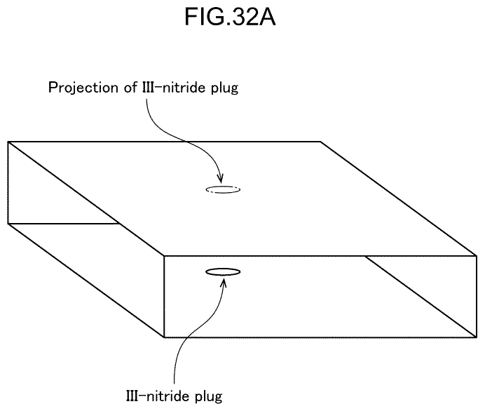

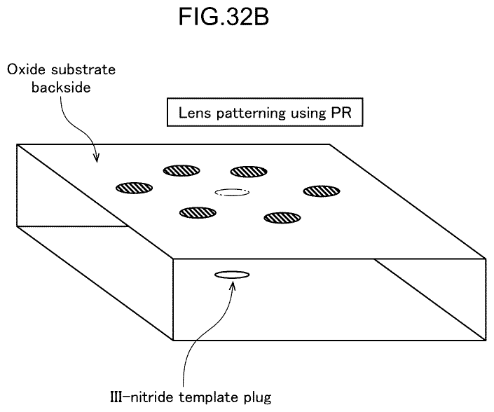

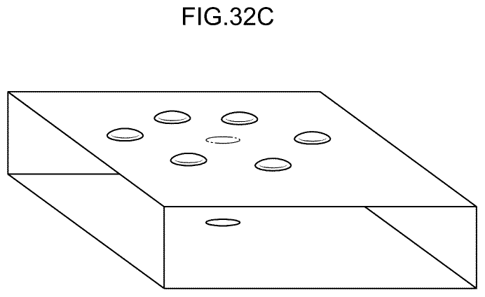

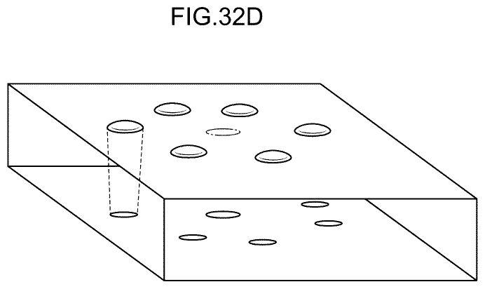

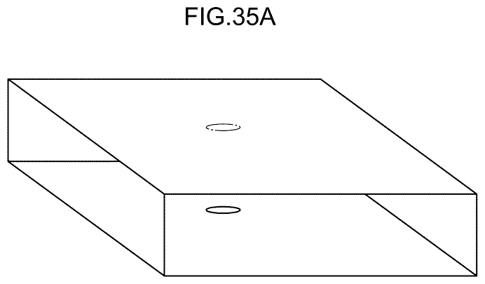

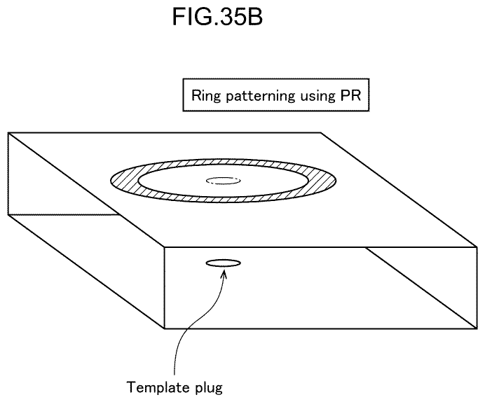

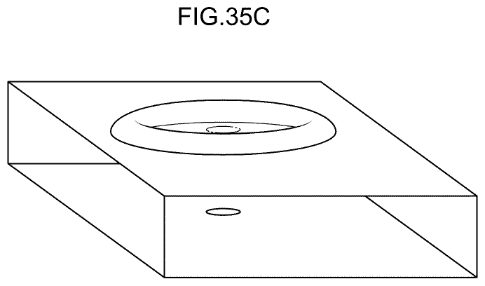

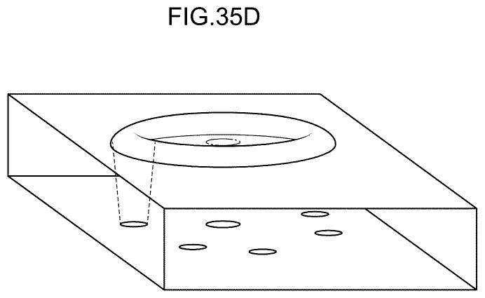

FIG. 9 illustrates step 1 for fabricating the VCSEL. FIG. 10 illustrates step 2 for fabricating the VCSEL. FIG. 11 illustrates step 3 for fabricating the VCSEL. In step 1 to step 3 micro lenses are fabricated on the polished TO substrate material surface at predefined locations aligned such that the focus of the lens helps to process current confining aperture of the VCSEL. The micro lenses are fabricated using a thermal reflow technique [NPL 11]. Photoresist micro disks 45a are patterned on TO material by standard photolithography in step 1 and subsequently shaped into a lenticular shape on a hot plate at an elevated temperature 45b in step 2, and the lens transferred into TO substrate material 45c by reactive ion etching the sacrificial photoresist mask in step 3. Lens fabrication for the HCP VCSELs was similar as the stripe VCSELs, however, lens formulation describes discrete number as indicated in FIGS. 32A, 32B, 32C and 32D, or lens formulation describes a continues ring as indicated in FIGS. 35A, 35B, 35C and 35D.

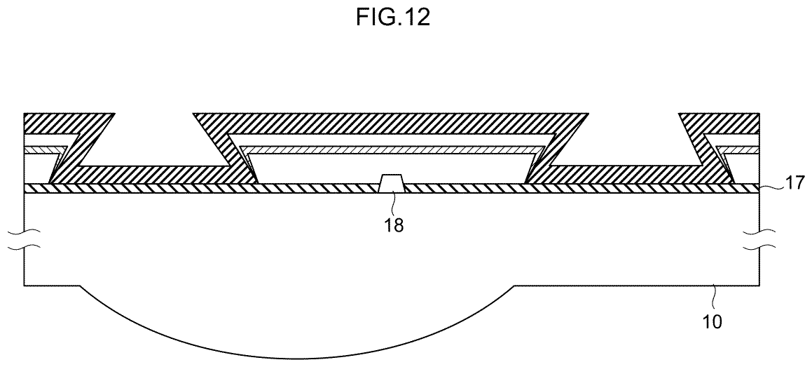

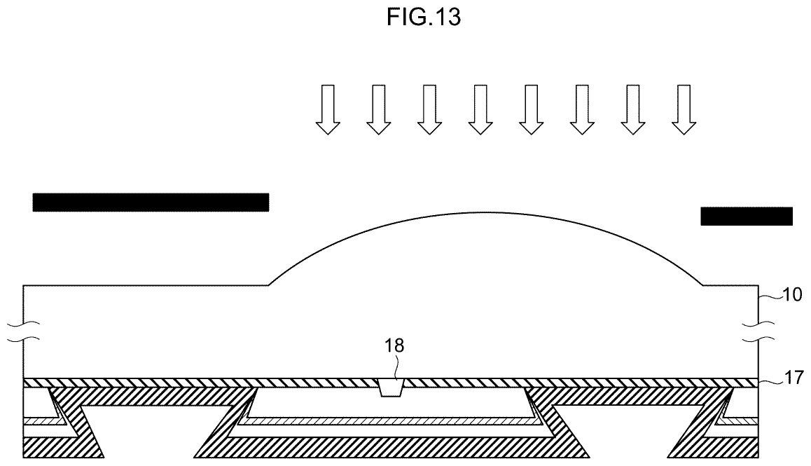

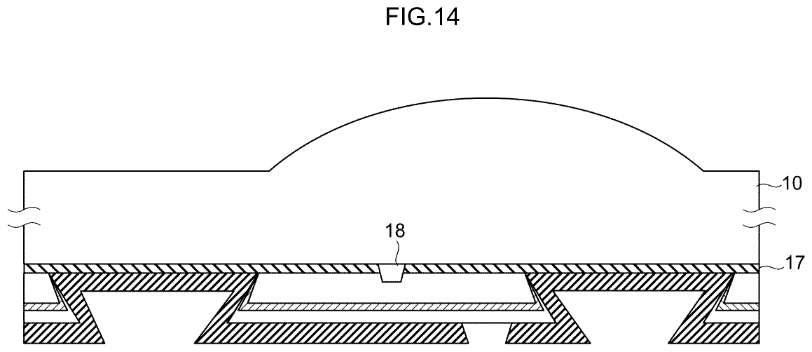

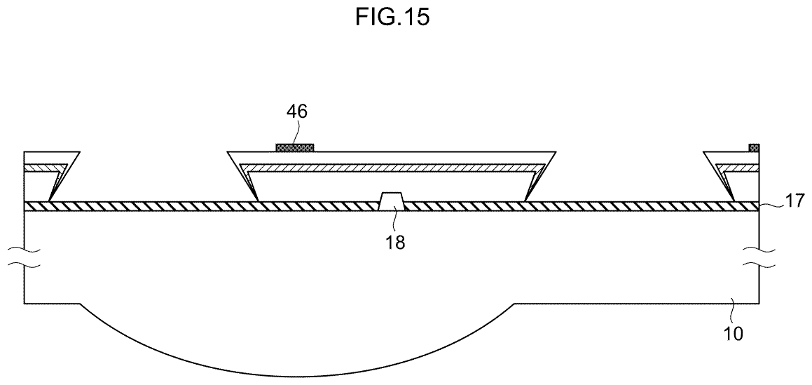

FIG. 12 illustrates step 4 for fabricating the VCSEL. FIG. 13 illustrates step 5 for fabricating the VCSEL. FIG. 14 illustrates step 6 for fabricating the VCSEL. FIG. 15 illustrates step 7 for fabricating the VCSEL.

Step 4 to step 7 show steps that utilize the shaped lens on the back surface TO substrate material to accurately define conducting aperture region. Step 4 shows a blanket deposited photoresist covering the device layers. Step 5, light exposure via the back of the TO substrate material, wherein pre-formed lens focuses the light onto semiconductor section 15 edge as per the design. Therefore, photosensitive material that was affected by the light reaction will be dissolved in the development stage leaving an aperture in the resist (step 6). Step 7 shows a deposited mask in the patterned region. This patterned mask 46 can be used as a protective mask during the fabrication of aperture region 39a and isolation region 39b or can also be used to etch only p++ GaN and n++ GaN layers in buried tunnel junction design. The protective mask can be a Ti/Au or dielectric or photoresist. Alternatively, aperture defining step can also be performed from the top surface without using the lens on the TO substrate in such case lens can be prepared at the last stage of the device fabrication. After Step 7, a regrowth is performed when VCSEL designs include burred tunnel junction or a tunnel junction as current spreading layer.

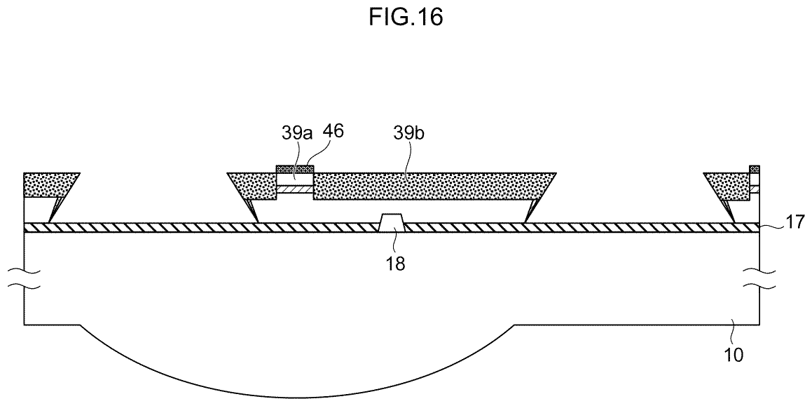

FIG. 16 illustrates step 8 for fabricating the VCSEL. Step8, in order to produce a semiconductor aperture region 39a from the semiconductor section 15, a mask 46, such as resist or metal protective mask, is formed on the semiconductor section 15. The implantation of ion, such as hydrogen atom, n-type dopant atom, and/or p-type dopant atom, into the semiconductor laminate 15 with a mask 46 produces an aperture structure for the semiconductor section 15. The aperture structure is provided with a semiconductor aperture region 39a extending in the first axial direction Ax1 and an isolation region 39b which surrounds the semiconductor aperture region 39a. The first DBR mirror 13, the aperture region 39a, and the second DBR mirror 41 are arranged along an axis, and the aperture structure is at least 3 micrometers away from the III nitride template plug 18.

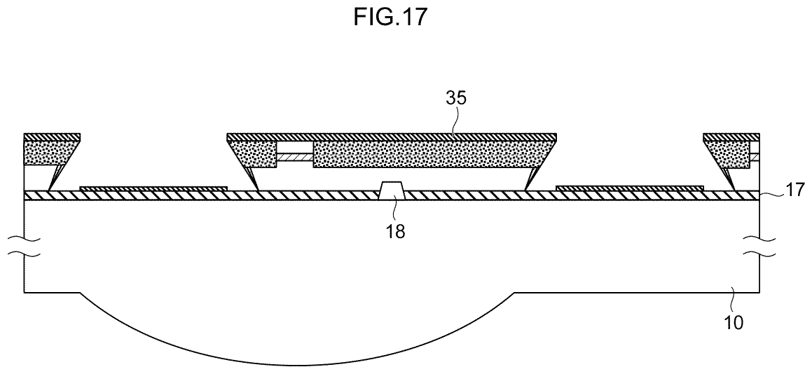

FIG. 17 illustrates step 9 for fabricating the VCSEL. After removing the mask 46, as shown in step 9, a conductive layer 35 is deposited on the aperture structure, which covers the semiconductor aperture region 39a and the isolation region 39b. The conductive layer 35 may include a heavily-doped III nitride semiconductor layer, such as GaN or AlGaN, and/or an inorganic layer, such indium tin oxide (ITO). The conductive layer arranged such a way that placement matches minimum (node) of the electromagnetic radiation to avoid absorption of light that was generated from the III nitride active region 27.

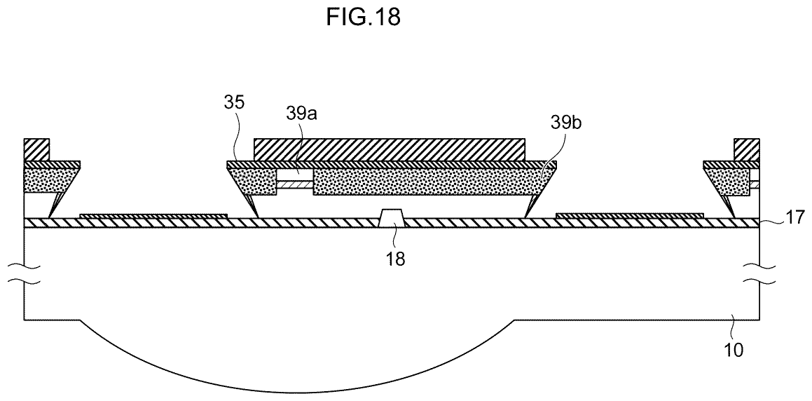

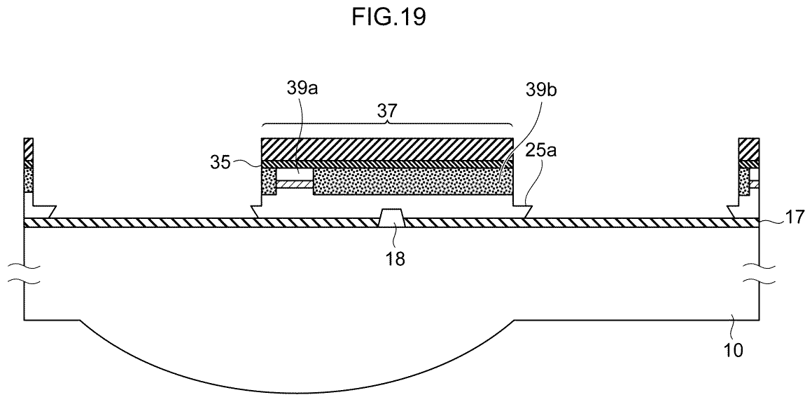

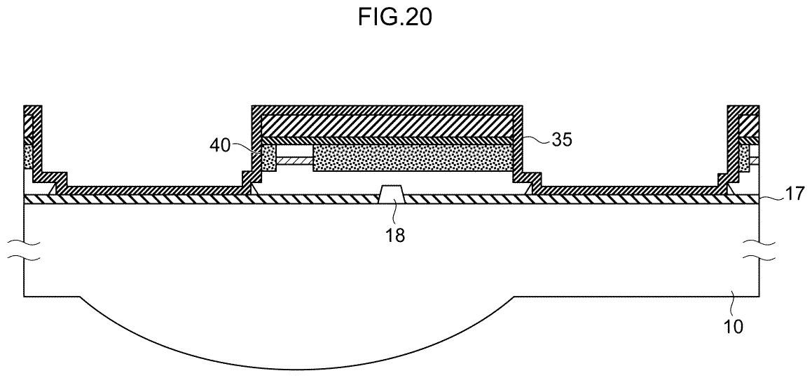

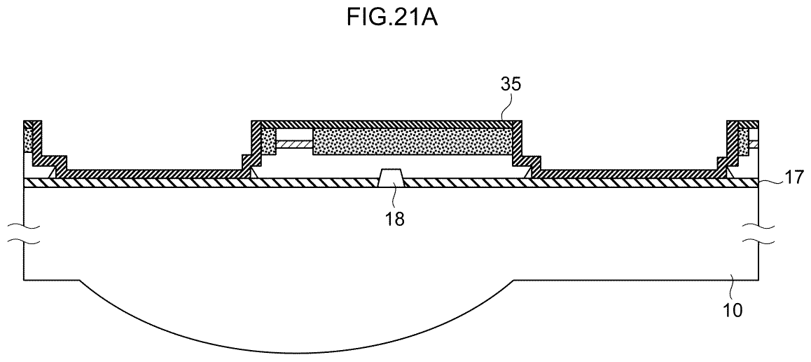

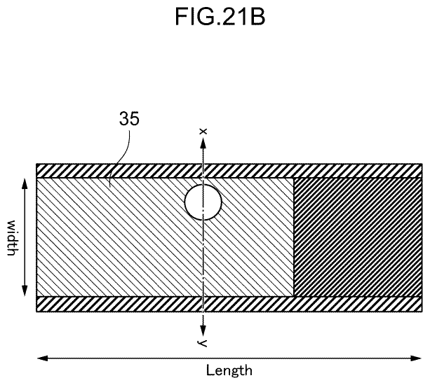

FIG. 18 illustrates step 10 for fabricating the VCSEL. FIG. 19 illustrates step 11 for fabricating the VCSEL. FIG. 20 illustrates step 12 for fabricating the VCSEL. FIG. 21A illustrates step 13 for fabricating the VCSEL. FIG. 21B is schematic top view showing the VCSEL in step 13.

Step 10 to step 16 show fabrication of the VCSEL as shown in step 10, a photoresist material is deposited to define a mesa 37. Mesa 37 is a rectangular photoresist patch covering aperture and nearly 50% of the chip surface, however for the HCP case is a circular patch. Then step 11 selectively etches the semiconductor section 15 to expose underlying n−GaN region of the III-nitride layer 25a. Then in step 12, an omnidirectional reflector, ODR, 40 placed, wherein ODR 40 functions to reflect operational wavelength of the VCSEL back into the cavity and also functions as passivation layer between anode electrode 31 and cathode electrode 33 and assists in avoiding short circuit. Subsequently, in step 13 lift off performed to leave ODR covering the whole etched sidewalls and exposed III-nitride n−GaN 25a.

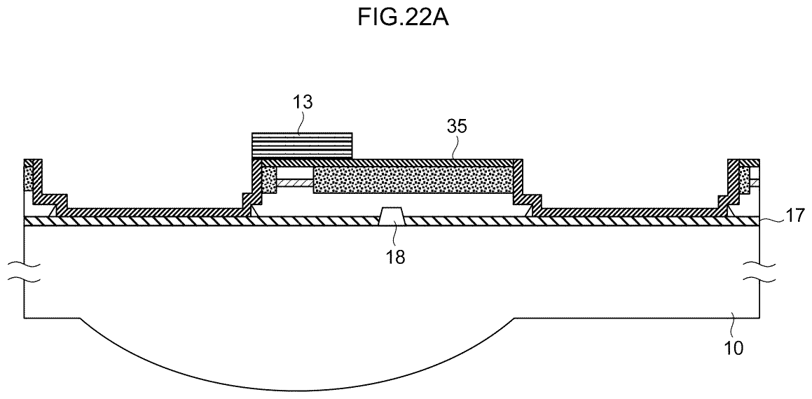

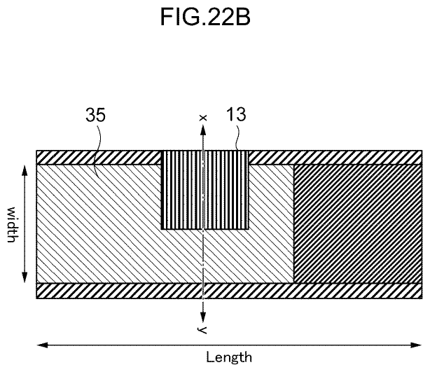

FIG. 22A illustrates step 14 for fabricating the VCSEL. FIG. 22B is schematic top view showing the VCSEL in step 14. As shown in step 14, a distributed Bragg reflector (DBR) 13 is formed on the conductive layer 35, and specifically, first dielectric layers and second dielectric layers are deposited alternately to form the arrangement of these dielectric layers.

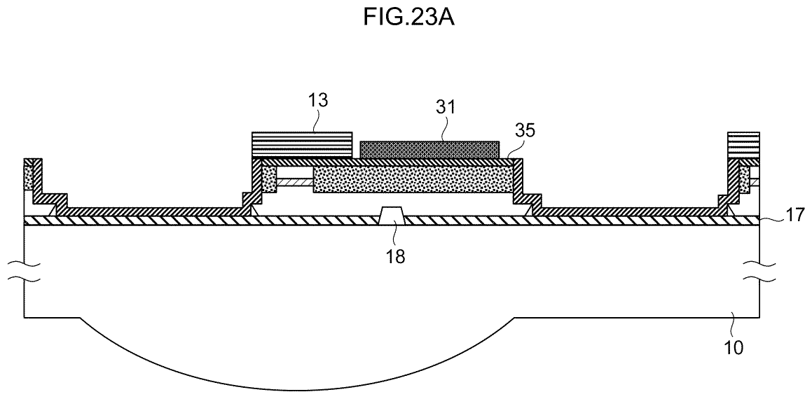

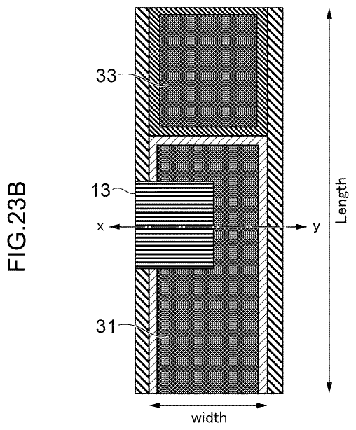

FIG. 23A illustrates step 15 for fabricating the VCSEL. FIG. 23B is schematic top view showing the VCSEL in step 15. As shown in step 15, mask openings, such as using resist, is formed on conductive layer 35 and on etched III-nitride n−GaN region 25a covered in ODR. ODR 40 is then etched to expose underlying n−GaN surface 25a as in FIG. 23B. Then anode electrode 31 on conductive layer 35 and a cathode electrode 33 across chip length are formed for electrical injection.

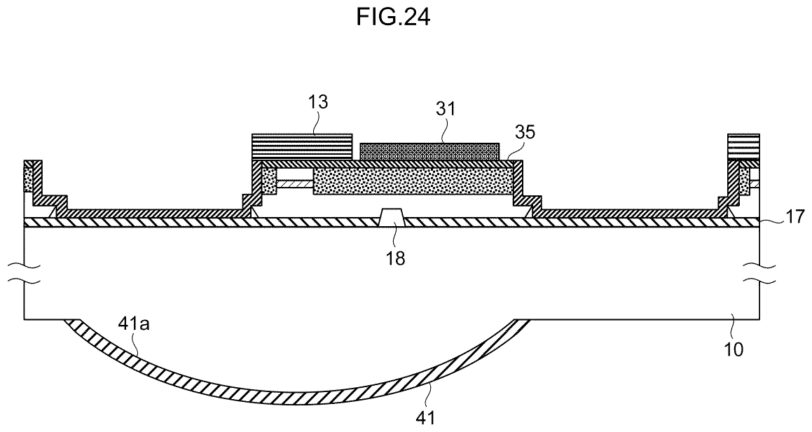

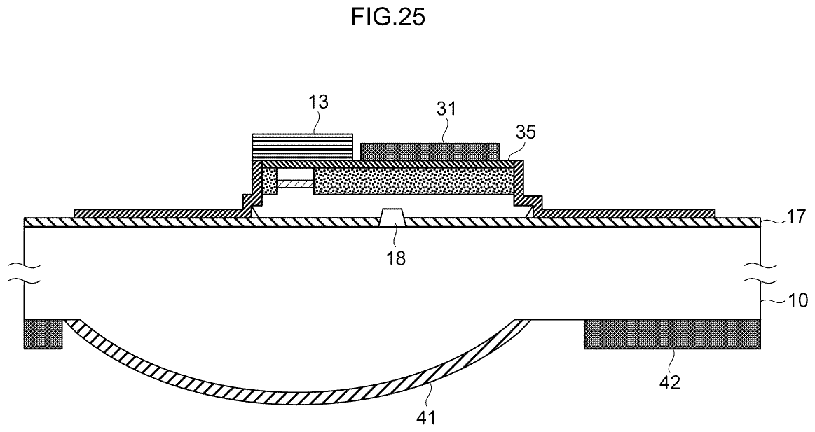

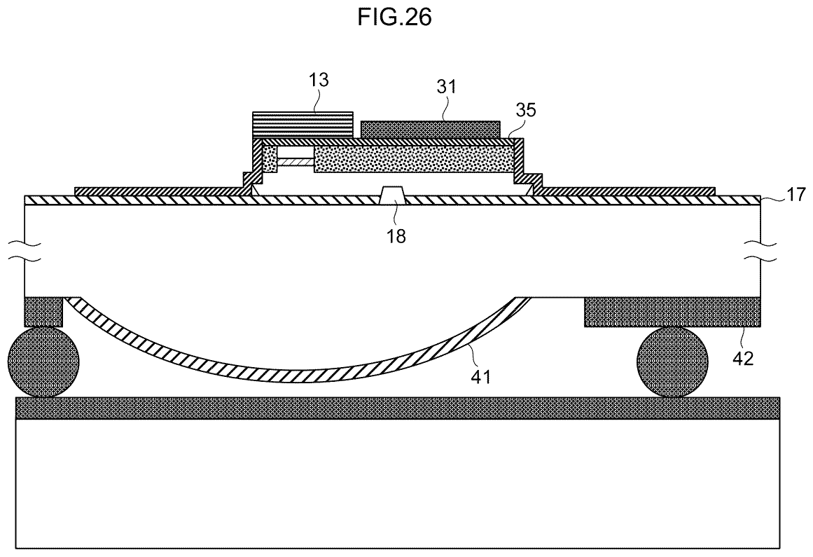

FIG. 24 illustrates step 16 for fabricating the VCSEL. FIG. 25 illustrates step 17 for fabricating the VCSEL. FIG. 26 illustrates step 18 for fabricating the VCSEL. In step 16, a second DBR mirror 41 is formed on TO substrate material curved surface. In the step 17, bonding material 42 placed at selected regions to enable sub mount bonding. As shown in step 18, the product VCSEL is bonded to sub mount on curved DBR side using solder bumps.

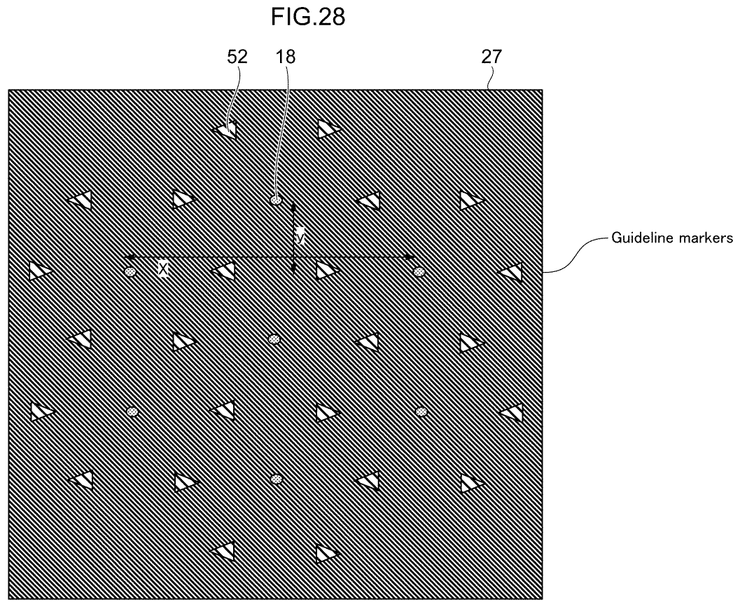

FIG. 27 is a schematic view showing a VCSEL according to a fourth embodiment of the present disclosure. FIG. 27 illustrates an AR layer 27 to partially embed the template plug 18. As described template plug 18 can be circular patches of diameter <5 microns arranged in a 2D triangular lattice passion as in FIG. 27. The distance between patches in a triangular lattice is arranged at desired dimensions. Further, variations in patch designs such as adding guideline markers 52 with a dielectric material without obstructing the chip dimensions can be placed as illustrated in FIG. 28. The guideline markers 52 can be any arbitrary shape, for example a triangular guidemarkers 52 vertex can impose a stress along the cleavable plane of the III-nitride region to singulate each chip when needed.

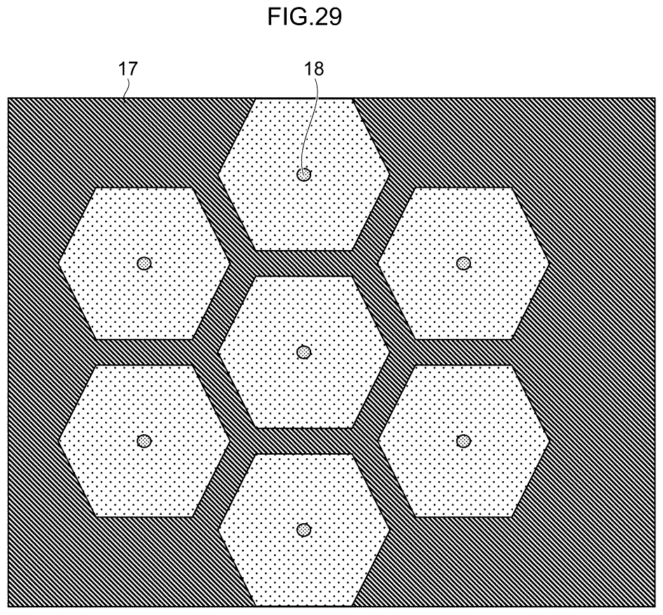

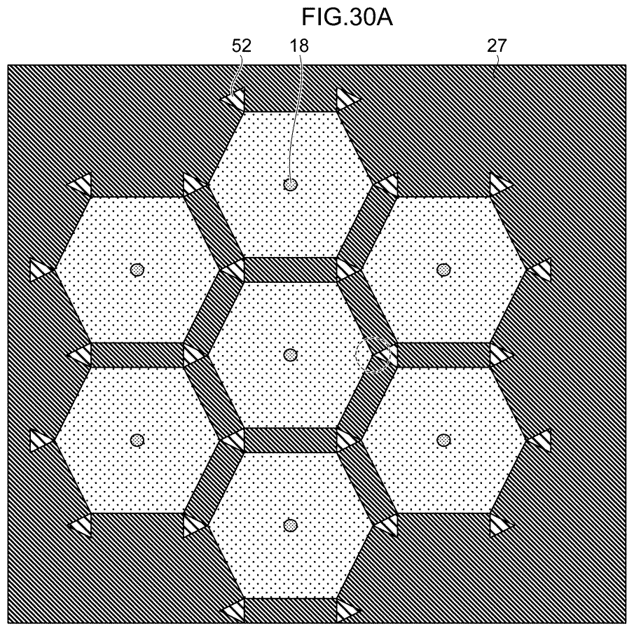

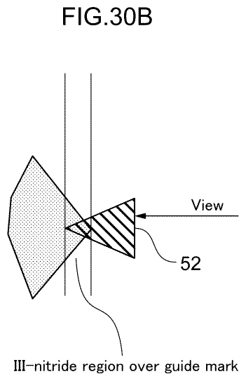

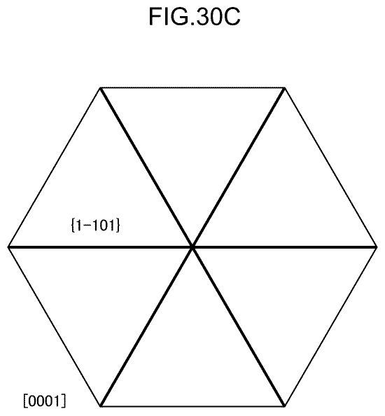

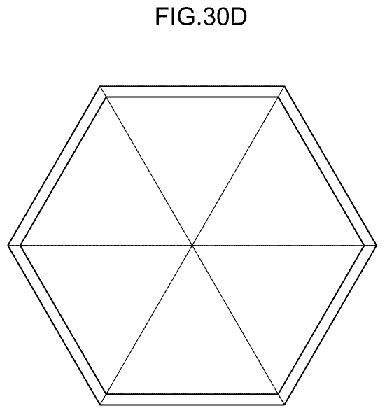

FIG. 29 and FIG. 30A are the descriptions of the HCP initial III-nitride base growth without/with guidemarkers. FIG. 30B is an enlarged view of the guideline marker 52 of FIG. 30A. For example, when a c-plane growth of GaN layer over the oxide substrate 10 by MOCVD process results in the formation of six faceted pyramid shape in a wide variety of growth conditions as described in FIG. 30C. The angle between (0001) plane and the side plane is approximately 62 degrees, which are semipolar {1-101} type planes. The growth rate of (0001) plane is relatively fast compared to {1-101} planes as a result (0001) plane appears to be vanished. However, with proper parameter optimization one can slow down the growth rate of (0001) plane and can obtain a proper chip area as described in FIG. 30C or FIG. 30D can also be achieved by polishing pyramid III-nitride layers in FIG. 30C. The growth rate of (0001) plane is relatively higher compared to {1-101} plane as a result (0001) plane disappears but it will present at an equilibrium state. Growth rates of planes vary under different growth conditions an optimized growth parameter can be used to reach FIG. 30B or even polishing may be used.

When guideline markers 52 are placed, III-nitride semiconductor region forms over the guide mark 52, which is an added piece on the AR layer 17 at the desired position. A magnified view of the overlaid ELO III-nitride semiconductor layer on the guideline mark 52 is shown in FIG. 30B.

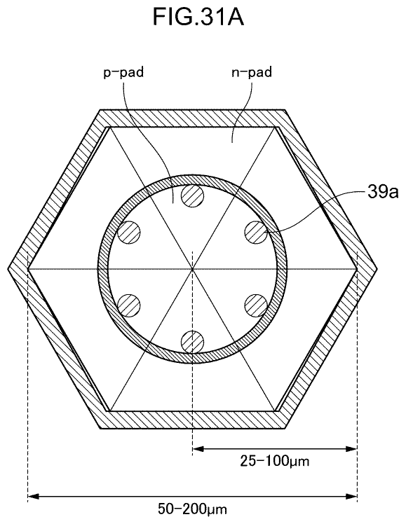

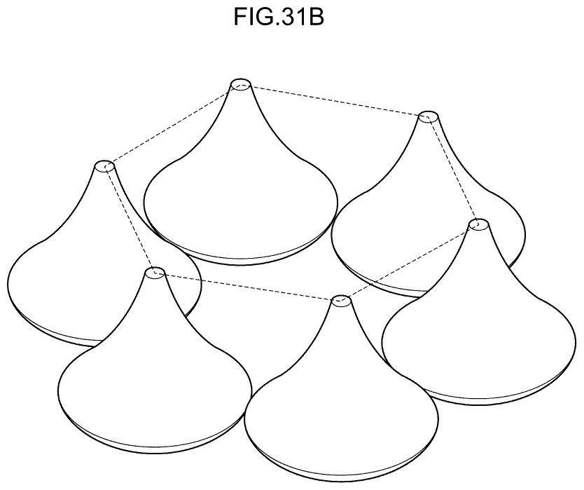

FIGS. 31A and 31B is a preferred design for HCP VCSEL type. Where p-pads were placed on the side of template plug 18 and n-pads were on the other side. Light emitting aperture was placed in between p-pad and n-pad. After finishing growth of all the necessary device layers for the VCSEL fabrication, six lens structure were fabricated on the back of the oxide substrate 10 using the transparent nature of oxide and III-nitride regions. Precise alignment between light injection and the radiation focusing lens is possible when lens fabricated first and then the same lens then used to define current aperture.

FIGS. 32A, 32B, 32C and 32D show the steps for forming six lenses in a concentric ring fashion using PR material. The lenses fabrication via photolithography and resist reflow have long been used to manufacture lens arrays. First, photoresist, PR, is spin-coated onto the substrate, soft baked, and exposed as normal as in FIG. 32B. After developing, photo resist cylinders remain. The resist cylinders are then placed onto hotplate that is set above glass transition temperature, causing the polymerous resist to abruptly transition from its amorphous rubbery state into a glass state system. The surface tension minimizes the surface area by rearranging the liquid masses inside of the cylinder/droplet.

Ideally, the resist melts completely, with masses freely transported and the surface tension forming a spherical micro lens. Then the lens shape is transferred onto the substrate via dry etching using reactive ion etching or any other as in FIG. 32C. The transferred lens on the substrate will be used in the process of formation of current aperture by focusing lithography light via back of the lens as in FIG. 32D. One of such illustration is given in FIGS. 32A, 32B, 32C and 32D

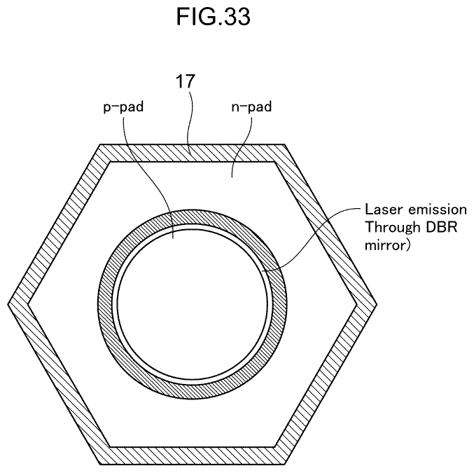

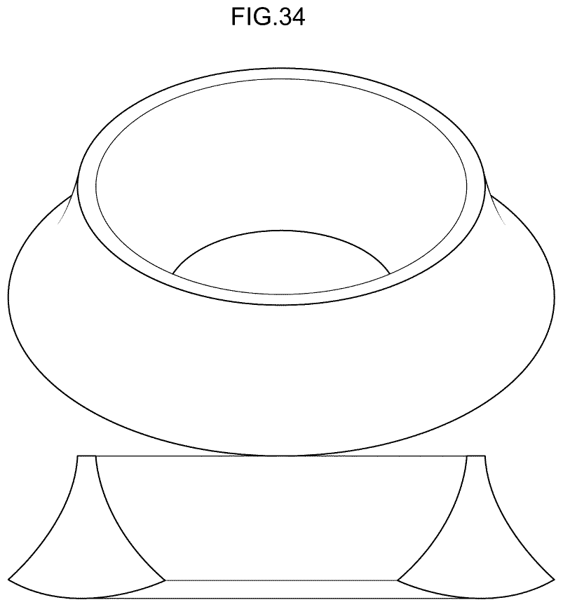

FIGS. 33, 34, 35A. 35B, 35C and 35D descriptions are analogous to the FIGS. 31A, 31B, 32A, 32B, 32C and 32D. Where instead of a discrete aperture a continue ring-like emission can be achieved. The aperture structure is a ring like continuous aperture structure concentric around the III-nitride template plugs 18 disposed triangular lattice. In this design lens on the back of the oxide substrate is like donut-like ring. PR pattern photolithographically formed like donut-shape and then thermal reflow was used as described above. The concentric donut lens structure on the oxide substrate 10 is then reused to form a ring-like light emitting aperture on the III-nitride semiconductor device region. In the presence of current injection light emission can be like a ring—as described in the FIG. 34. Circular ring emissions can be designed in this particular design. As this chip design uses whole HCP chip, one-common p-pad and common n-pad are placed on either side of the emitting region.

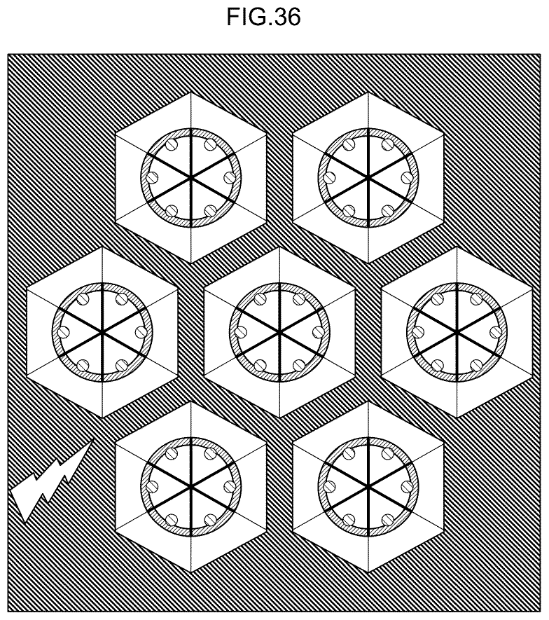

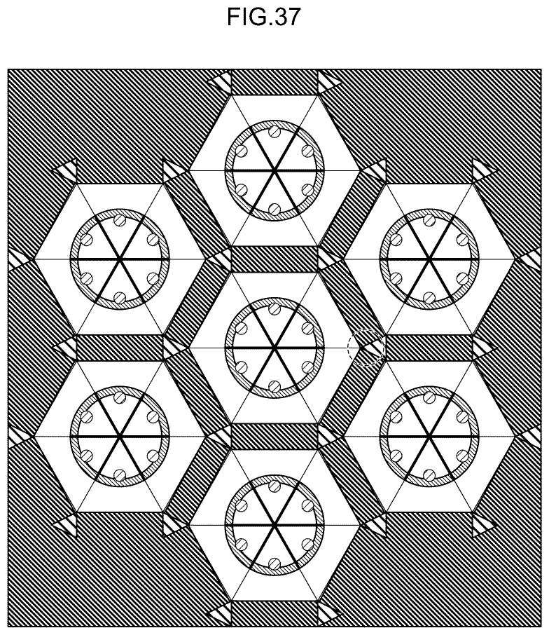

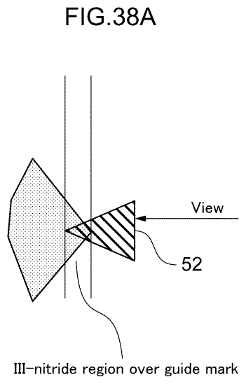

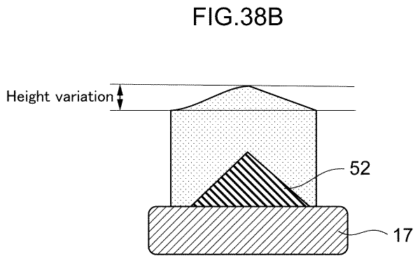

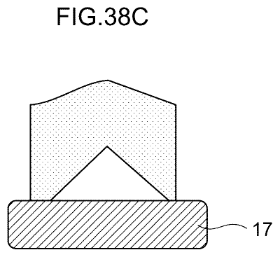

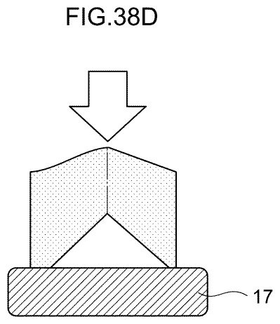

HCP designs are better in increasing yield. To break them into individual chips, especially for HCP-type1. Guide marks 52 can be placed at the initial stage of the ELO process. Resulting design patterns look like the ones shown in FIG. 36 (without guide marks) and as in FIG. 37 with guide marks 52. FIG. 38A is an enlarged view of the guide mark 52 shown in FIG. 37.

FIG. 36 where no guide markers were used, the ELO layers growth was stopped before coalescing with a neighboring layer. The gap between them is preferred to be around 10 micrometers. Now in order to separate them into a block of VCSELs containing HCP structures and each HCP is a combination of at least 6 VCSELs a laser stealth process can be employed. Stealth laser dicing (“Stealth Dicing Process” <URL: https://www.disco.co.jp/eg/solution/library/laser/stealth. html>) where laser can be accurately focused to cut the VCSELs into blocks. Using this process street widths down to 10 microns at a desired configurations die/blocks can be carved at ease from wafer.

FIGS. 38B, 38C and 38D is a design to separate isolate each individual VCSEL chip from HCP structure. The device layers in this case extend their corners onto guide marks 52. Due to local height difference around the guideline marker device layers shows a little bump at the guiding mark 52. Alternatively, this height variation can be minimized during the polishing step after base III-nitride layers growth. The guideline markers 52 extend a pressure on the cleavable plane of III-nitride semiconductor device. The separation process is illustrated schematically in FIGS. 38B, 38C and 38D. In this separation of individual blocks can be performed via laser stealth process and individual VCSEL chip preparation can be done by cleaving.

For the cleaving, after removing guide marking material downward pressure is applied on the device surface from top. When downward pressure applied on the strained III-nitride device, III nitride layer breaks along the cleavable plane. Alternatively, even when height variation leveled during the polishing, downward pressure still be able to break the III-nitride layer along the cleavable plane. Once the individual chips separated using downward pressure mechanism, laser stealth process is applied to separate VCSELs into blocks.

A plurality of aperture structures are concentric around the III-nitride template plugs 18 disposed triangular lattice and each aperture structure is a single chip.

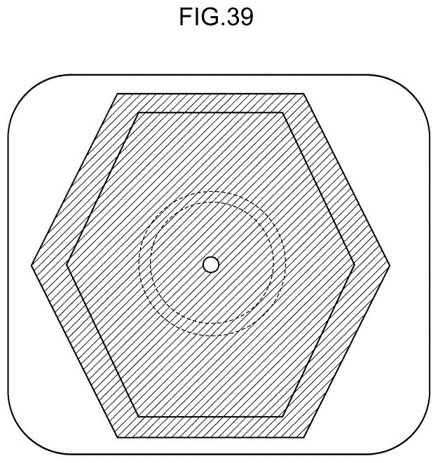

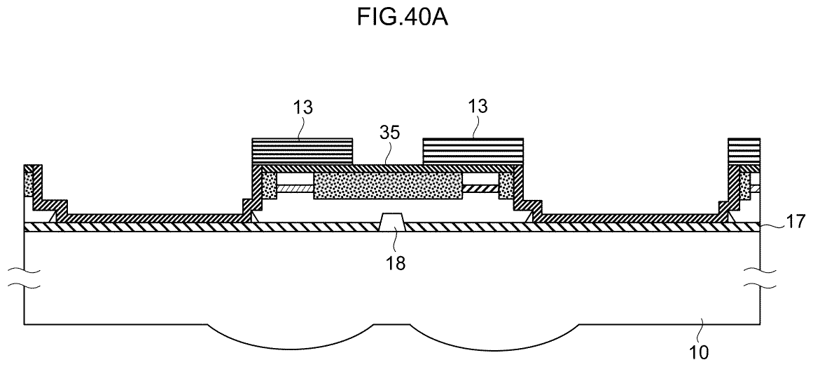

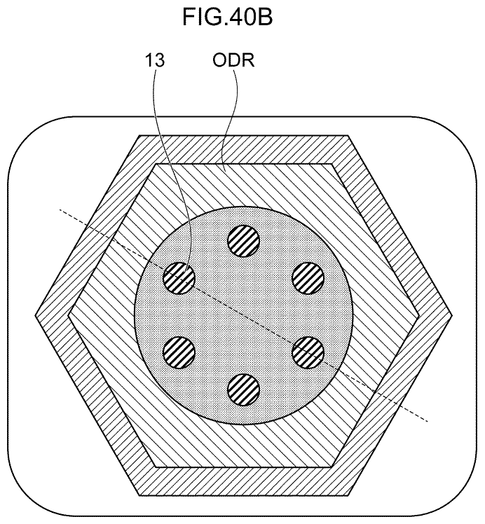

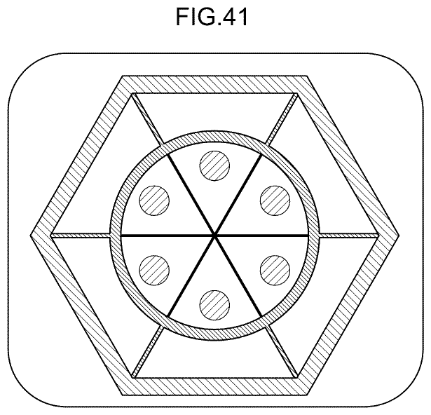

The steps for fabricating a VCSEL processed with an HCP design are similar to those described above for fabricating a VCSEL in which the template plug 18 is striped. However, FIGS. 39, 40A, 40B and 41 show the steps for fabricating a VCSEL processed with an HCP design. FIG. 39 is a top view of a VCSEL in a step grown from III-nitride template plugs 18 by epitaxial lateral overgrowth to form III-nitride islands. FIG. 40A shows step 14 for fabricating the VCSEL. FIG. 40B shows a top view of the VCSEL at step 14. FIG. 41 shows a top view of the VCSEL at step 15 for fabricating the VCSEL.

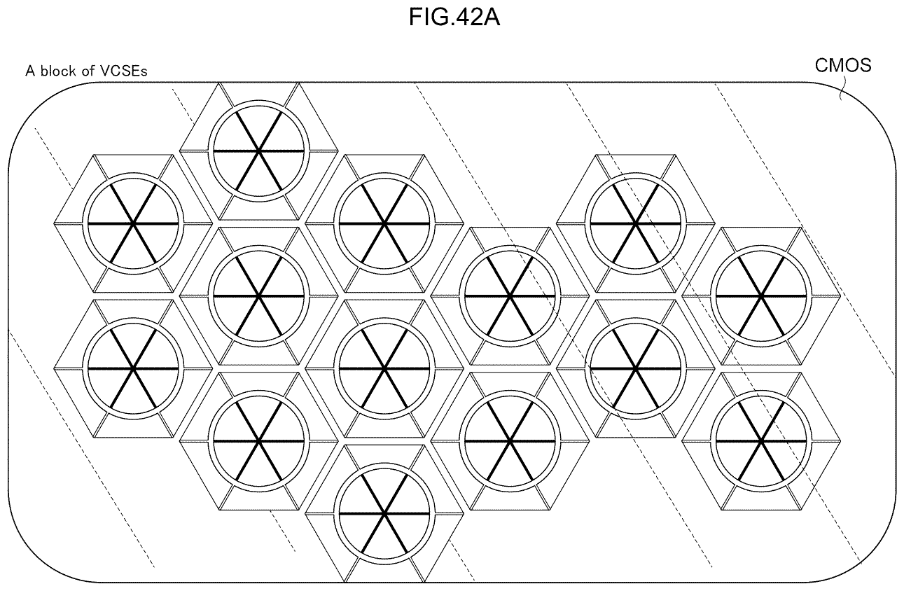

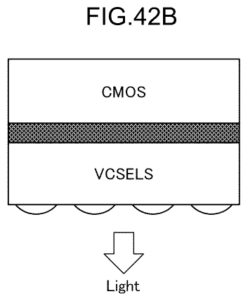

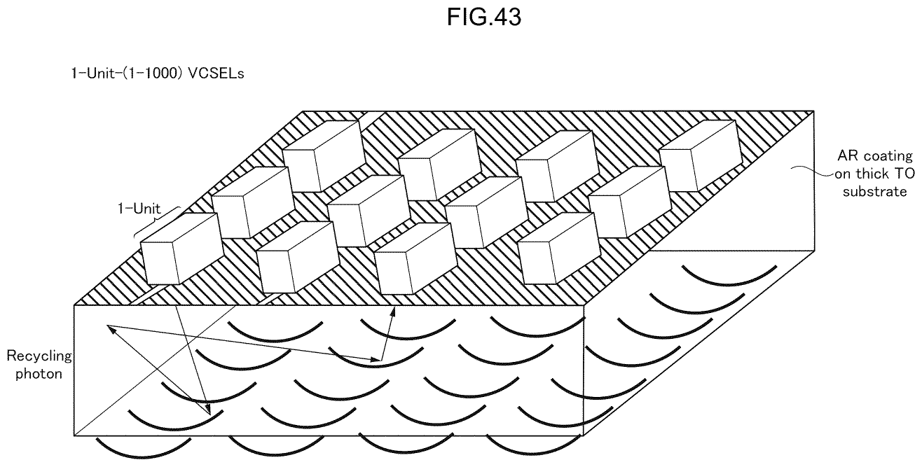

High density of VCSELs processed in HCP design can be seen in FIG. 42A. One can cut several tens or hundreds of VCSELs as thick blocks using cleaving or cleaving plus laser stealth or only using laser stealth. Now a day CMOS technology is very advantageous and can go even lines below 1 micrometer. Adding CMOS technology with the highly packed VCSELs technology of the present invention as in FIG. 42B would serve several applications including display, automotive headlights, projection and augmented and virtual reality. Light emission from the VCSEL can be managed by changing the reflectivity of DBR mirrors, for this particular case mentioned in FIG. 42B, bottom light was made to emit from curved DBR mirror by managing its reflectance. FIG. 43 shows an overview of a VCSEL that utilizes recycling photons. Wherein photons recycling concept, VCSEL blocks containing more than one VCSEL are carved using laser stealth process and the sides of the block are coated with AR or ODR material to block photons leakage from sides. The photons internally circulated in the block and used in one of the cavities of VCSEL.

### Definitions:

Transparent oxide (TO) substrate material:

The lens shape is formed in a transparent oxide (TO) substrate material. The same material is used in the growth of device layers. To substrate material, such as ZnO, Ga₂O₃, Al₂O₃ etc can be used. This allows the VCSEL cavity to be mainly dominated by absorption less TO substrate. As TO substrate material such as sapphire can be available in larger size i.e more than 6-inch manufacturing of this procedure results more yield from a single run.

Template plug:

Starting with a TO material substrate having a III-nitride template, wherein template thickness can be 1 micron to 10 microns. Crystalline quality of the template increases with increased thickness. The threading dislocations that originated at the substrate interface due to lattice mismatch terminate with increased thickness. Furthermore, larger thickness may allow to use thick AR layer structures.

Starting with a planar template on a TO material substrate a selective etching is performed in a direction on the TO substrate that would enhance lateral growth. For example, stripes parallel to <11-20> axis in a III-Nitride layer. When (0001) polar III-nitride template films etched to expose (11-22) sidewalls, lateral growth from such sidewalls can be enhanced.

Alternatively, template step shape can be arbitrary on a condition that allows enhanced growth of III-nitride layer along the filter.

Epitaxial Lateral Overgrowth:

The TO substrate material with III-nitride template is shaped in the form of stripes or HCP, template plugs 18, wherein the template plug 18 sidewalls are partially embedded in AR filter structure made of all dielectric materials such as SiO₂, Ta₂O₅, HfO₅ etc while leaving top surface intact. Preferably, template thickness is designed to accommodate thick AR layer in order to achieve better quality for the overgrown III-nitride ELO layers. The stripes can be longer or cut to match the length of the device. If a polar template is used stripes are oriented along <11-20> axis, if a nonpolar template is used, the stripes are oriented along a <0001> axis. If a semipolar (20-21) or (20-2-1) template is used, the stripes are oriented in a direction parallel to [−1014] or [10-14], respectively. Other planes may be use as well, with the stripes orienting oriented in other directions. In the HCP pattern, patterns can be circles or the small hexagons where sides matched with the ELO growth of the C-plane III-nitride layer.

The TO substrate material containing partially exposed template step sidewalls is placed in MOCVD to grow III-nitride layers. In one embodiment, the growth pressure ranges from 50 to 760 Torr, although the growth pressure preferably ranges from 100 to 300 Torr to obtain a wide width for the island-like III-nitride semiconductor layers; the growth temperature ranges from 900 to 1200° C. degrees; the V/III ratio ranges from 10-30,000; the TMG is from 2-20 sccm; NH₃ ranges from 0.1 to 10 slm; and the carrier gas is only hydrogen gas, or both hydrogen and nitrogen gases. To obtain a smooth surface, the growth conditions of the III-nitride layers optimized. Finally, the III-nitride ELO GaN layer 25 is stopped when thickness reached about 1-10 μm and a width ~50 μm, with each wing spanning around 15 micrometers.

The TO substrate material comprising growth region (exposed template step) and a non-growth region (the AR layer) can be characterized with fill factor. The substrate surface without above features identical to planar growth processes a fill factor, 1. When the fill-factor deviates from 1, there is a high possibility that III-nitride atoms may accumulate more at the edge of the layer due to abundancy of III-nitride atoms at the growth and non-growth interface resulting a thicker GaN layer at the edge of the III-nitride island compared to the center region, designated as edge growth 26.

Polishing:

The edge growth increases for very small fill factor due to excess amount of carrier gases and metal organics. III-nitride island layers tend to approach concave shape. The edge growth tends to be problem when III-nitride base layers of thickness ~5-10 micrometers grown from a template step initially. It is recommended to planarize the surface before the growth of any further device layers comprising p−GaN, n−GaN and InGaN and AlGaN layers. Planarization at this stage of the device also helps in controlling cavity thickness. As the device layers including n−GaN, MQW, p−GaN and tunnel junction layers all together may not exceed ~700 nm during the regrowth after polishing resulting a very negligible edge growth.

Device layers growth: III-nitride-based semiconductor layers, tunnel junctions and buried tunnel junctions

The semiconductor section 15 laminate composed III-nitride semiconductor device layers can include In, Al and/or B, as well as other impurities, such as Mg, Si, Zn, O, C, H, etc.

The III-nitride-based semiconductor device layers generally comprise more than two layers, including at least one layer among an n-type layer, an undoped layer and a p-type layer. The III-nitride-based semiconductor device layers specifically comprise a GaN layer, an AlGaN layer, an AlGaInN layer, an InGaN layer, etc. For example, epitaxial growth of the device layers carried in MOCVD after polishing the III-nitride GaN layer 25. The active region comprises 2× MQW (3 nm wells and 7 nm barriers), 10-nm p-AlGaN electron-blocking layer (EBL), 100 nm p−GaN and 10 nm p++GaN.

When ITO is employed as current spreading layer device layers growth should be ended at p++GaN. Otherwise, an additional 10 nm thick n++GaN layer must be deposited on top of p++ GaN for the buried tunnel junction. For the buried tunnel junction and the tunnel junction cases a current speeding layer n−GaN of ~50 nm deposited during regrowth.

In the tunnel junction design growth paused at p++ GaN and then continued after conducting ion-implantation, whereas for the buried tunnel junction case growth stopped after adding 10 nm thick n++ GaN over p++ GaN. The regrowth can be either carried in MOCVD or MBE (molecular beam epitaxy). MBE was used instead of MOCVD to eliminate hydrogen repassivation of p−GaN during tunnel junction regrowth.

Alternatively, the present design described in one of the embodiments processes a discreet or island like III-nitride device layers. Therefore, activation of p−GaN can be achieved through lateral diffusion even the p−GaN layer embedded in tunnel junction layer or current spreading layer (n−GaN). Therefore, the particular discreet device layers design gives a freedom in choosing MBE or MOCVD depending on the manufacturability parameters such as cost and yield.

Microlens formation:

Aperture fabrication procedure on the VCSEL described in these embodiments can utilize a lensing effect of curved surface which will function as the second DBR mirror in the VCSEL product.

The TO substrate material can be a double side polished substrate, therefore micro lens pattern on the back of the surface arranged such that the resulting lens shape should later assist in accurately aligning an aperture at the edge of semiconductor section.

Photoresist (PR) re-flow and dry-etch method used to fabricate micro lens. For example, double side polished sapphire substrates (0001)-oriented 2-in wafers can be used. Alternatively larger diameter wafer can also be used. An array of circular PR disks patterned on the back of the polished sapphire substrate by standard photolithographic technique. The PR patterns are then baked on a hot plate at an elevated temperature. After reaching transition temperature PR patterns start to flow forms a convex shape with the center of each pattern the thickest. Subsequent pattern transfer to the sapphire substrate can be done with an inductively coupled plasma (ICP) system. With optimized etching conditions surface roughness below nanometer can be achieved. Preferably, etched surface on the sapphire must have a surface roughness between 0.1 nm to 0.5 nm to avoid wavelength scattering and the corresponding loss.

Ion implantation:

Ion implantation is used to form an electrical, optical aperture in the GaN-based layer by damaging the GaN-based layer outside the aperture, and damaged GaN-based material is no longer conductive. This method keeps the surface planar and can provide a very slight index guiding between the aperture region and the damaged region. The damaged region can be, however, provided with the potential to increase an optical loss in the cavity, and tends to have higher absorption values than the un-implanted material of the aperture region. Heavy ions, such as aluminum (Al), boron (B), etc., can be used for ion implantation procedure.

The basic idea of the ion implantation is to create a conducting aperture. After ion implantation a transparent conducting layer defined later can be laminated over the device layers or a regrowth performed on device layers with or without non implantation for the tunnel junction scenarios.

Transparent conductive layer:

ITO can be used as a commonly used transparent current spreading layer. The inclusion of ITO to the VCSEL may cause an additional absorption, but the additional absorption can be decreased by making the intensity of the electro-magnetic wave low around the ITO layer. Alternative approaches, such as tunnel junctions, can also be used to spread current and make the optical absorption low.

Tunnel junction:

A tunnel junction allows hole injection into the p-side of the device through an n-type semiconductor. This is achieved by using a junction between a highly-doped n-type region and a highly-doped p-type region under a reverse bias, allowing electrons to tunnel from the valence band of the p-type region to the conduction band of the n-type region. As the tunneling probability depends exponentially to tunneling distance, a highly doped regions are preferred (~10¹⁹/cc or above) to produce a thin depletion width for efficient operation.

When device layer growth stopped after p++ GaN. Ion implantation conducted by using a lensing effect from the processed curved surface back of the TO substrate material. Then the sample reintroduced for the consequent growth of current spreading layer epitaxially. Preferably, a 10/50 nm thickness n++/n−GaN layers epitaxially regrown.

Buried tunnel junction:

In a buried tunnel junction device, the highly doped region is confined to the aperture of the VCSEL device only such that the current flow through the area with high doping. If a low doping is used everywhere else to bury the junction, then almost current flow is restricted to the aperture until the junction breakdown voltage reached. This is achieved by growing a planar tunnel (p++/n++/10 nm/10 nm) and then etching the highly doped junction layers at the desired aperture position using lens of the TO substrate material. Then a regrowth is conducted to bury the etched high dope layers via epitaxially growing a thick current spreader n−GaN layer. Alternatively, ion implantation may also be conducted before regrowing a current spreader to bury tunnel junction

DBR mirror:

DBR mirror includes alternating dielectric layers joined together to form a reflective mirror on top of the resonant cavity of the VCSEL. For example, a combination of SiO₂/Ta₂O₅ dielectric quarter wavelength thick layers can be used as a dielectric DBR mirror. The number of pairs on the p-side of the device should be smaller than curved side (n-side) to promote light emission.

Omni directional reflector (ODR):

Omnidirectional reflector is like dielectric mirror but not as severe as DBR mirror. ODR is designed to reflect light that leaks out of the propagation path back into the cavity. ODR can also be used to protect or passivate anode and cathode electrodes from direct contact.

Metal Pads:

Metals, such as gold (Au), aluminum (Al), nickel (Ni), palladium (Pd), titanium (Ti), Indium (In) and so on, are used as material of metal pads at several stages of VCSEL fabrications. Some combinations can be uses as protective masks and some for current injection. The metal layer can be formed by sputtering, evaporating, or plating.

### Applications

Lighting:

GaN based LEDs have led to dramatic shift in residential and automotive lighting. Lighting in combination with communication services are very desirable in the future smart city and smart infrastructures. VCSELs are better alternatives to LEDs and edge emitting laser diodes. However, not having a proper profitable mass production techniques stopping GaN VCSELs entering market. The procedures developed in the above embodiments can be used to mass produce VCSEL units that applicable in lighting applications.

Visible light communication:

Laser light for potential data transfer and communication applications through light fidelity (LiFi). With the rapid increase of IoT devices the demand on data transmission continues to expand. The RF spectrum is getting saturated and new frequencies are needed to keep up with the continuously growing demand. A GaN VCSEL adoption into existing LED architecture is simpler than replacing with an edge emitting laser. Therefore, the device described in the above embodiments could serve the purpose.

Near eye displays:

Near eye displays represent the next major wave of consumer electronics. They are the basis of virtual reality (VR) and augmented reality (AR) technology. Currently, micro-LEDs are predominant choice for displays, however despite the limited progress in VCSEL research, VCSELs must be introduced as miniature display and near eye display. Relatively low optical power is beneficial in maintaining eye safety. Low divergence and circular symmetry reduce additional optical elements thus leads to compactness. The 2D array integration capability of VCSELs is simpler than edge emitting lasers. Therefore, the VCSEL product made using invention can be applied in these applications.

### Advantages

A sufficiently long cavity without excessive diffraction losses can be used with two reflecting mirrors that define the VCSEL cavity.

Thermal management can be improved with a sufficiently long cavity and/or contact placement to the nitride layer.

A GaN template plug included in the device interfaces with a better thermally conductive TO substrate material, thereby improving thermal performance.

Inexpensive large template substrates such as GaN on Sapphire can be used.

Waste of semiconductor layers can be minimized by using island-like growth of III-nitrides.

Additional substrate removal and bonding procedures can be eliminated, thus improves production parameters.

GaN substrates with high-quality and larger size are very expensive. The present ELO technique can unlock the usage of foreign substrates in the production of VCSELs.

This invention is expected to provide a significant improvement in the performance and reduction in the manufacturing cost and eliminating complex procedures.

This invention proposes to use AR layer integration in the VCSEL enabling epitaxial lateral overgrowth to improve quality of crystalline layers.

Using a template TO material substrate like GaN/Sapphire, high crystalline quality layers possible as the invention use device layers that are on epitaxial lateral overgrown wing, which in general defect free or having fewer defects.

Efficient photon recycling happens, because the interface between semiconductor region and TO substrate was made to reduce scattering and VCSEL chips were cut into thick blocks. TO substrate thick block sidewalls can be AR coated to trap the scattered phonons from the TO substrate AR layer interface. These scattered photons will be used somewhere in the VCSEL block to produce lasing action. This advantage is sketched in FIG. 43.

A curved mirror is formed on a transparent oxide (TO) substrate, and a semiconductor section is provided on the AR layer of the extended cavity of the TO material. Therefore, the diffraction loss can be reduced because the curved mirror can collect the light.

The AR layer functions as bonding material between TO substrate and semiconductor section and as a mask layer for ELO growth.

The curved mirror refocuses all the electromagnetic radiation back into the gain region of the device.

The template plug helps to grow semiconductor section on the AR layer. This feature is important for several purposes. Firstly, in the extended cavity design light that passes past the AR layer into the TO substrate should not see semiconductor section (III-Nitride layer) as this will increase the absorption. Secondly, for thermal improvement and reducing defects.

Hexagonal growth is effective outcome when polar c-plane III-nitride semiconductor part growth is desired. Mostly c-plane substrates are desired as they are available in large size more than 2-inch and in less cost. Also, this feature increases chip density, thus the yield.

Aspect 1

A VCSEL comprises: an oxide substrate having a first face, and a second face at an opposite side from the first face, the second face including a curved surface;
a semiconductor section disposed on the first face of the oxide substrate;
a lossless antireflective (AR) layer disposed between the semiconductor section and the first face of the oxide substrate;
a first distributed Bragg reflector (DBR) mirror, the semiconductor section being disposed between the AR layer and the first DBR mirror; and
a second DBR mirror disposed at the curved surface of the oxide substrate, the first DBR mirror, the semiconductor section, the AR layer, the oxide substrate, and the second DBR mirror being arranged in a first axial direction to form an extended cavity,
the semiconductor section including a p-type III nitride region, a III nitride region, and a III nitride active region between the p-type III nitride region and the III nitride region, the p-type III nitride region, the III nitride active region, and the III nitride region being arranged in the first axial direction, and the III nitride region including an n-type III nitride region.

Aspect 2

In the VCSEL according to the aspect 1, the semiconductor section and the oxide substrate are connected via a III-nitride template plug.

Aspect 3

In the VCSEL according to aspect 1 or 2, The VCSEL according to claim 1, wherein the VCSEL is configured without using a III-nitride material on the oxide substrate side of the AR layer.

Aspect 4

In the VCSEL according to any one of aspects 1 to 3, the AR layer surface roughness is lower than 1 nm.

Aspect 5

In the VCSEL according to aspect 2, the AR layer has a through hole extending in the first axial direction, and
the III nitride template plug is disposed in the through hole and extends from the first face of the oxide substrate to the semiconductor section in the through hole.

Aspect 6

In the VCSEL according to aspect 2, the III nitride template plug facilitates regrowth of a high crystalline quality semiconductor device layer over the AR layer.

Aspect 7

In the VCSEL according to aspect 2, the III-nitride template plug is configured by a triangular lattice or a regular arrangement of strips.

Aspect 8

In the VCSEL according to aspect 2, the semiconductor section includes an aperture structure, the aperture structure including an aperture region extending in the first axial direction, and an isolation region surrounding the aperture region, and the first DBR mirror, the aperture region, and the second DBR mirror are arranged along an axis, and the aperture structure is disposed at least 3 micrometers away from the III nitride template plug.

Aspect 9

In the VCSEL according to aspect 2, the curved surface of the oxide substrate has a center line, and the III nitride template plug and the center line of the curved surface are not aligned with each other.

Aspect 10

In the VCSEL according to any one of aspects 1 to 9, a plurality of semiconductor sections are formed by growth in accordance with a hexagonal closed packed (HCP) design, and the curved surfaces comprise a plurality of curved surfaces arranged so as to correspond to the plurality of semiconductor sections.

Aspect 11

In the VCSEL according to aspect 8, a plurality of the aperture structures are concentric around the III-nitride template plugs disposed in the triangular lattice and each aperture structure comprises a single chip

Aspect 12

In the VCSEL according to aspect 8, the aperture structure is a ring-like continuous aperture structure that is concentric around the III-nitride template plugs disposed in the triangular lattice.

Aspect 13

In the VCSEL according to any one of aspects 1 to 12, guide marks are included in the AR layer.

Aspect 14

In the VCSEL according to aspect 13, VCSEL chips are singularized by cleaving assisted by the guide marks.

Aspect 15

In the VCSEL according to any one of aspects 1 to 14, the VCSEL is separated into blocks by a laser stealth process.

Aspect 16

In the VCSEL according to any one of aspects 1 to 15, a length of the extended cavity is more than 50 micrometers.

Aspect 17

In the VCSEL according to any one of aspects 1 to 3, the oxide substrate includes any one of ZnO, SiO2, Ga2O3, Al2O3, or Ta2O5.

Aspect 18

In the VCSEL according to any one of aspects 1 to 13, a crystal orientation of the III-nitride template plug in the VCSEL is c-plane, semipolar or non-polar.

Aspect 20

A method for fabricating a VCSEL comprises: preparing a starting base, the starting base including an oxide base, a III nitride template plug, and a lossless antireflective (AR) layer, the oxide base having a first face and a second face at an opposite side from the first face of the oxide base, and the AR layer and the III nitride template plug being located at the first face of the oxide base; growing a III nitride region from the III nitride template plug on the AR layer; after growing the III nitride region, growing a semiconductor laminate including an n-type III nitride region, a III nitride active region, and a p-type III nitride region; processing the oxide base at the second face thereof to form an oxide substrate having a curved surface, the curved surface being disposed at an opposite side from a first face of the oxide substrate; after growing the semiconductor laminate, forming a first distributed Bragg reflector (DBR) laminate on the first face of the oxide substrate; and forming a second DBR laminate on the curved surface of the oxide substrate.

Aspect 21

The method according to aspect 20, further comprising, prior to growing the semiconductor laminate, planarizing the III nitride region by at least one of polishing or etching.

Aspect 22

The method according to aspect 20 or 21 further comprises, after growing the semiconductor laminate and prior to forming the first DBR laminate, depositing a conductive layer on the first face of the oxide substrate; and forming a first electrode on the conductive layer.

Aspect 23

The method according to any one of aspects 20 to 22 further comprises producing a mesa structure from the semiconductor laminate by etching to form an etched face of the n-type III nitride region, the mesa structure including the III nitride active region.

Aspect 24

The method according to aspect 23 further comprises forming a second electrode on the etched face of the n-type III nitride region outside the mesa structure.

Aspect 25

In the method according to any one of aspects 20 to 24, the semiconductor laminate further includes one of a tunnel junction or a buried tunnel junction.

Aspect 26

In the method according to any one of aspects 20 to 25, preparing the starting base comprises: depositing a III nitride layer on the first face of the oxide base; patterning the III nitride layer to form the III nitride template plug; depositing multiple dielectric layers to cover the first face of the oxide base and the III nitride template plug; and processing the multiple layers to form the AR layer such that the III nitride template plug is located in a through hole of the AR layer, and the III nitride template plug has a height that is greater than a thickness of the AR layer.

Aspect 27

In the method according to any one of aspects 20 to 26, the III nitride region is grown from the III nitride template plug by epitaxial lateral overgrowth to form a III nitride island.

Aspect 28

In the method according to aspect 27, the III nitride island extends along a top face of the AR layer from the III nitride template plug outward, and the top face of the AR layer has a roughness that is lower than one nanometer.

Aspect 29

In the method according to any one of aspects 20 to 28, the III nitride active region is grown to form a quantum well structure configured to generate light having a wavelength in a first reflection spectrum of the first DBR laminate, and in a second reflection spectrum of the second DBR laminate.

Aspect 30

In the method according to any one of aspects 20 to 29, processing the oxide base at the second face thereof to form an oxide substrate comprises forming a patterned resist layer on the second face of the oxide base, thermally treating the patterned resist layer to form a convex resist region, and transferring a shape of the convex resist region to the oxide base by etching the convex resist region and the oxide base to form the curved surface, and
etching the convex resist region and the oxide substrate is stopped so as to satisfy a condition that, after forming the first DBR laminate and the second DBR laminate, a distance between the second DBR laminate and the first DBR laminate is more than 50 micrometers.

Aspect 31

The method according to any one of aspects 20 to 30, further comprises, after growing the semiconductor laminate and prior to forming the conductive layer, forming a resist film on the first face of the oxide substrate; illuminating the resist layer through the curved surface of the oxide substrate to produce a patterned mask from the resist film; and performing ion implantation with the patterned mask to form an aperture structure including an aperture region and an isolation region surrounding the aperture region.

Having described and illustrated the principle of the invention in a preferred embodiment thereof, it is appreciated by those having skill in the art that the invention can be modified in arrangement and detail without departing from such principles. We therefore claim all modifications and variations coming within the spirit and scope of the following claims.

### REFERENCE SIGNS LIST

10 oxide substrate
11 VCSEL
13, 41 distributed Bragg reflector (DBR)
15 semiconductor section
17 AR layer
23 p-type III nitride region
25 n-type III nitride region
27 III nitride active region
29 cavity
31 anode electrode
33 cathode electrode
35 conductive layer
37 mesa
39a aperture region
39b isolation region
52 guiding mark
Ax1 axial direction

1. A vertical cavity surface emitting laser (VCSEL), comprising:
an oxide substrate having a first face, and a second face at an opposite side from the first face, the second face including a curved surface;
a semiconductor section disposed on the first face of the oxide substrate;
a lossless antireflective (AR) layer disposed between the semiconductor section and the first face of the oxide substrate;
a first distributed Bragg reflector (DBR) mirror, the semiconductor section being disposed between the AR layer and the first DBR mirror; and
a second DBR mirror disposed at the curved surface of the oxide substrate, the first DBR mirror, the semiconductor section, the AR layer, the oxide substrate, and the second DBR mirror being arranged in a first axial direction to form an extended cavity,
the semiconductor section including a p-type III nitride region, a III nitride region, and a III nitride active region between the p-type III nitride region and the III nitride region, the p-type III nitride region, the III nitride active region, and the III nitride region being arranged in the first axial direction, and the III nitride region including an n-type III nitride region.

2. The VCSEL according to claim 1, wherein the semiconductor section and the oxide substrate are connected via a III-nitride template plug.

3. The VCSEL according to claim 1, wherein the VCSEL is configured without using a III-nitride material on the oxide substrate side of the AR layer.

4. The VCSEL according to claim 1, wherein the AR layer surface roughness is lower than 1 nm.

5. The VCSEL according to claim 2, wherein:
the AR layer has a through hole extending in the first axial direction, and
the III nitride template plug is disposed in the through hole and extends from the first face of the oxide substrate to the semiconductor section in the through hole.

6. The VCSEL according to claim 2, wherein the III nitride template plug facilitates regrowth of a high crystalline quality semiconductor device layer over the AR layer.

7. The VCSEL according to claim 2, wherein the III-nitride template plug is configured by a triangular lattice or a regular arrangement of strips.

8. The VCSEL according to claim 2, wherein the semiconductor section includes an aperture structure, the aperture structure including an aperture region extending in the first axial direction, and an isolation region surrounding the aperture region, and the first DBR mirror, the aperture region, and the second DBR mirror are arranged along an axis, and the aperture structure is disposed at least 3 micrometers away from the III nitride template plug.

9. The VCSEL according to claim 2, wherein the curved surface of the oxide substrate has a center line, and the III nitride template plug and the center line of the curved surface are not aligned with each other.

10. The VCSEL according to claim 1, wherein a plurality of semiconductor sections are formed by growth in accordance with a hexagonal closed packed (HCP) design, and the curved surfaces comprise a plurality of curved surfaces arranged so as to correspond to the plurality of semiconductor sections.

11. The VCSEL according to claim 8, wherein a plurality of the aperture structures are concentric around the III-nitride template plugs disposed in the triangular lattice and each aperture structure comprises a single chip.

12. The VCSEL according to claim 8, wherein the aperture structure is a ring-like continuous aperture structure that is concentric around the III-nitride template plugs disposed in the triangular lattice.

13. The VCSEL according to claim 1, wherein guide marks are included in the AR layer.

14. The VCSEL according to claim 13, wherein VCSEL chips are singularized by cleaving assisted by the guide marks.

15. The VCSEL according to claim 1, wherein the VCSEL is separated into blocks by a laser stealth process.

16. The VCSEL according to claim 1, wherein the VCSEL includes a blocking outer surface coated with an antireflective material that prevents photons from escaping.

17. The VCSEL according to claim 1, wherein a length of the extended cavity is more than 50 micrometers.

18. The VCSEL according to claim 1, wherein the oxide substrate includes any one of ZnO, SiO₂, Ga₂O₃, Al₂O₃, or Ta₂O₅.

19. The VCSEL according to claim 1, wherein a crystal orientation of the III-nitride template plug in the VCSEL is c-plane, semipolar or non-polar.

20. A method for fabricating a vertical cavity surface emitting laser (VCSEL), the method comprising:
preparing a starting base, the starting base including an oxide base, a III nitride template plug, and a lossless antireflective (AR) layer, the oxide base having a first face and a second face at an opposite side from the first face of the oxide base, and the AR layer and the III nitride template plug being located at the first face of the oxide base;
growing a III nitride region from the III nitride template plug on the AR layer;
after growing the III nitride region, growing a semiconductor laminate including an n-type III nitride region, a III nitride active region, and a p-type III nitride region;
processing the oxide base at the second face thereof to form an oxide substrate having a curved surface, the curved surface being disposed at an opposite side from a first face of the oxide substrate;
after growing the semiconductor laminate, forming a first distributed Bragg reflector (DBR) laminate on the first face of the oxide substrate; and
forming a second DBR laminate on the curved surface of the oxide substrate.

21. The method according to claim 20, further comprising, prior to growing the semiconductor laminate, planarizing the III nitride region by at least one of polishing or etching.

22. The method according to claim 20, further comprising:
after growing the semiconductor laminate and prior to forming the first DBR laminate, depositing a conductive layer on the first face of the oxide substrate; and
forming a first electrode on the conductive layer.

23. The method according to claim 20, further comprising producing a mesa structure from the semiconductor laminate by etching to form an etched face of the n-type III nitride region, the mesa structure including the III nitride active region;

24. The method according to claim 23, further comprising forming a second electrode on the etched face of the n-type III nitride region outside the mesa structure.

25. The method according to claim 20, wherein the semiconductor laminate further includes one of a tunnel junction or a buried tunnel junction.

26. The method according to claim 20, wherein preparing the starting base comprises:
depositing a III nitride layer on the first face of the oxide base;
patterning the III nitride layer to form the III nitride template plug;
depositing multiple dielectric layers to cover the first face of the oxide base and the III nitride template plug; and
processing the multiple layers to form the AR layer such that the III nitride template plug is located in a through hole of the AR layer, and the III nitride template plug has a height that is greater than a thickness of the AR layer.

27. The method according to claim 20, wherein the III nitride region is grown from the III nitride template plug by epitaxial lateral overgrowth to form a III nitride island.

28. The method according to claim 27, wherein the III nitride island extends along a top face of the AR layer from the III nitride template plug outward, and the top face of the AR layer has a roughness that is lower than one nanometer.

29. The method according to claim 20, wherein the III nitride active region is grown to form a quantum well structure configured to generate light having a wavelength in a first reflection spectrum of the first DBR laminate, and in a second reflection spectrum of the second DBR laminate.

30. The method according to claim 20, wherein:
processing the oxide base at the second face thereof to form an oxide substrate comprises forming a patterned resist layer on the second face of the oxide base, thermally treating the patterned resist layer to form a convex resist region, and transferring a shape of the convex resist region to the oxide base by etching the convex resist region and the oxide base to form the curved surface, and
etching the convex resist region and the oxide substrate is stopped so as to satisfy a condition that, after forming the first DBR laminate and the second DBR laminate, a distance between the second DBR laminate and the first DBR laminate is more than 50 micrometers.

31. The method according to claim 20, further comprising:
after growing the semiconductor laminate and prior to forming the conductive layer, forming a resist film on the first face of the oxide substrate;
illuminating the resist layer through the curved surface of the oxide substrate to produce a patterned mask from the resist film; and
performing ion implantation with the patterned mask to form an aperture structure including an aperture region and an isolation region surrounding the aperture region.
